(19) United States
(12) Patent Application Publication
(10) Pub. No.: US 2026/0150587 A1
(43) Pub. Date: May 28, 2026

(54) SUPERCONDUCTING DIODE DEVICES

(71) Applicants: President and Fellows of Harvard College, Cambridge, MA (US); Yeda Research and Development at the Weizmann Institute of Science, Rehovot (IL)

(72) Inventors: Amir Yacoby, Cambridge, MA (US); Shaowen Chen, Cambridge, MA (US); Seunghyun Park, Cambridge, MA (US); Uri Vool, Cambridge, MA (US); Nikola Maksimovic, Cambridge, MA (US); Adiel Stern, Rehovot (IL); Bertrand I. Halperin, Cambridge, MA (US)

(73) Assignees: President and Fellows of Harvard College, Cambridge, MA (US); Yeda Research and Development at the Weizmann Institute of Science, Rehovot (IL)

(21) Appl. No.: 19/041,721

(22) Filed: Jan. 30, 2025

Related U.S. Application Data
(60) Provisional application No. 63/627,662, filed on Jan. 31, 2024.

(51) Int. Cl. H10N 60/12; H10N 60/80; H10N 60/83

(52) U.S. Cl. CPC H10N 60/124; H10N 60/805; H10N 60/83

(57) ABSTRACT

Superconducting diodes and methods of operating the same are provided. A superconducting diode includes first and second superconducting portions separated by an asymmetric junction and a transverse electrode coupled to the first superconducting portion. Operating the superconducting diode includes applying a transverse current to the transverse electrode. Techniques described herein may serve as a building block for the continued development of superconducting circuits.

### CROSS-REFERENCE TO RELATED APPLICATIONS

This application claims the benefit under 35 U.S.C. § 119(e) of U.S. Provisional Patent Application No. 63/627,662, filed Jan. 31, 2024, and titled “NANOSCALE MAGNETOMETER FOR VISUALIZING CURRENT INDUCED HIDDEN STATES IN JOSEPHSON JUNCTIONS,” which is incorporated herein by reference in its entirety.

### GOVERNMENT FUNDING

This invention was made with government support under W911NF-22-1-0248 and W911NF-21-2-0147 awarded by U.S. Army Research Office (ARO) and under DE-AC05-00OR22725 awarded by U.S. Department of Energy (DOE) and under CW7492 awarded by Oak Ridge National Laboratory. The government has certain rights in this invention.

### BACKGROUND

Superconductors permit resistance-free flow of current under certain conditions (e.g., at temperatures below a critical temperature of the superconducting material). Circuits including superconducting devices and/or elements are envisioned for a variety of applications, including low-power computing circuitry, single photon detectors, and quantum computers.

### SUMMARY

Some embodiments are directed to a superconducting diode including: a junction device including a first superconducting portion and a second superconducting portion separated by an asymmetric junction; and a transverse superconducting electrode coupled to the first superconducting portion.

In some embodiments, the asymmetric junction includes a material having a finite resistance at an operational temperature of the superconducting diode.

In some embodiments, the material of the asymmetric junction includes a geometric asymmetry.

In some embodiments, the asymmetric junction includes a Dayem bridge superconducting portion having a notch.

In some embodiments, the superconducting diode further includes a controller configured to, during operation of the superconducting diode: cause application of a bias current to the first superconducting portion; and cause application of a transverse current to the transverse superconducting electrode.

In some embodiments, the first superconducting portion and the second superconducting portion each include a plurality of arms, and the asymmetric junction includes a plurality of junctions, each of the plurality of junctions connecting respective arms of the first superconducting portion and the second superconducting portion.

In some embodiments, a first junction of the plurality of junctions is characterized by a critical current different than a critical current of a second junction of the plurality of junctions.

In some embodiments, one or more junctions of the plurality of junctions comprise materials having a finite resistance at an operational temperature of the superconducting diode.

In some embodiments, the one or more junctions include: a first junction including a first material, and a second junction including a second material, wherein the first material and the second material are different.

In some embodiments, the asymmetric junction includes an asymmetry resulting from a geometry of one or more junctions of the plurality of junctions.

In some embodiments, one or more junctions of the plurality of junctions include a Dayem bridge superconducting portion having a notch.

In some embodiments, the transverse superconducting electrode is a first transverse superconducting electrode, and the superconducting diode further includes a second transverse superconducting electrode coupled to the second superconducting portion.

In some embodiments, the first superconducting portion and the second superconducting portion have a thickness of less than one hundred nanometers.

In some embodiments, the first superconducting portion and the second superconducting portion are separated by a distance of less than one micrometer.

In some embodiments, a distance from the asymmetric junction to the transverse superconducting electrode is less than one micrometer.

In some embodiments, the first superconducting portion and the second superconducting portion comprise niobium nitride (NbN).

In some embodiments, the first superconducting portion and the second superconducting portion comprise high temperature superconducting material.

In some embodiments, the techniques described herein relate to a method of operating a superconducting diode, the method including: applying a bias current to a first superconducting portion of a junction device, the first superconducting portion being separated from a second superconducting portion of the junction device by an asymmetric junction; and causing the junction device to act as a superconducting diode by applying a transverse current to a first transverse superconducting electrode coupled to the first superconducting portion.

In some embodiments, applying the transverse current includes controlling a polarity of the superconducting diode by selecting a direction of the applied transverse current.

In some embodiments, applying the transverse current includes controlling an efficiency of the superconducting diode by selecting a magnitude of the applied transverse current.

The foregoing apparatus and method embodiments may be implemented with any suitable combination of embodiments, features, and acts described above or in further detail below. These and other aspects, embodiments, and features of the present teachings can be more fully understood from the following description in conjunction with the accompanying drawings.

### BRIEF DESCRIPTION OF DRAWINGS

The patent or application file contains at least one drawing executed in color. Copies of this patent or patent application publication with color drawing(s) will be provided by the Office upon request and payment of the necessary fee.

Various aspects and embodiments will be described with reference to the following figures. It should be appreciated that the figures are not necessarily drawn to scale. In the drawings, each identical or nearly identical component that is illustrated in various figures is represented by a like numeral. For purposes of clarity, not every component may be labeled in every drawing.

FIG. 1 is a schematic diagram of an illustrative superconducting diode device and associated circuitry, in accordance with some embodiments of the technology described herein.

FIG. 2A is a schematic diagram of an illustrative superconducting diode having an asymmetric Josephson junction and a transverse electrode, in accordance with some embodiments of the technology described herein.

FIG. 2B is a schematic diagram of an illustrative superconducting diode having an asymmetric Josephson junction and a second transverse electrode, in accordance with some embodiments of the technology described herein.

FIG. 3A is a schematic diagram of an illustrative superconducting diode having multiple arms, each arm including an associated Josephson junction, and a transverse electrode, in accordance with some embodiments of the technology described herein.

FIG. 3B is a schematic diagram of an illustrative superconducting diode having multiple arms, each arm including an associated Josephson junction, and a second transverse electrode, in accordance with some embodiments of the technology described herein.

FIG. 3C is a schematic diagram of an illustrative superconducting diode having multiple arms, each arm including an associated Dayem bridge, in accordance with some embodiments of the technology described herein.

FIG. 4 is a flowchart illustrating a process 400 of operating a superconducting diode, in accordance with some embodiments of the technology described herein.

FIG. 5 is a schematic diagram of an illustrative implementation of a computer system that may be used in connection with some embodiments of the technology described herein.

FIGS. 6A-6B show a nitrogen-vacancy (NV) center measurement setup and expected Josephson current flow in a Josephson junction (JJ). FIG. 6A is a schematic showing a superconductor-normal-superconductor junction measured by scanning NV center embedded in a diamond tip. The superconductor (SC) wave function can be described by an amplitude and phase Ψ=|Ψ|e^{iθ}. Under external magnetic field B_{z}, the screening current near the JJ (dotted lines) induces a phase difference φₑ(x). The bias current causes a phase difference between the SC electrodes φ_{bias}. FIG. 6B is a graph showing measured differential resistance dV/dI versus perpendicular magnetic field B_{z} and bias current I_{dc}, at T=7 K. Dashed lines are the expected critical current, where the dotted line is φ_{bias}=π/2 and the dashed line is φ_{bias}=−π/2. The I_{c} nodes are denoted as ±Bₙ.

FIGS. 6C-6D are graphs showing calculated Josephson current normalized by critical current density for 0-Josephson vortex (JV) and 1-JV states, at external B_{z}=1.10 mT in FIG. 6C, and B_{z}=1.91 mT in FIG. 6D. The current flow is sine-like at zero bias current (bold lines), shifts along the x direction at a finite bias current, and becomes cosine-like at the critical current. FIG. 6E are simulations showing the Josephson current flow (top) and local SC phase (bottom) of the 0-JV and 1-JV states. The screening current near the junction Jₓ (black arrows) is reduced by the Josephson current J_{y} (white arrows) in the 0-JV state, and enhanced in the 1-JV state. This causes the Josephson current-induced phase. I_{bias}=0, B_{z}≈1.2 mT in this simulation.

FIG. 6F shows graphs of simulated φₑ(x) for 0-JV and 1-JV states, at the same B_{z} as FIG. 6E. φₑ(x) is the difference of 0 taken along the two dashed lines in each sub-panel of FIG. 6E.

FIG. 6G is an illustration showing NV control and current bias sequence based on the AC magnetometry protocol. The X(Y) microwave (MW) pulses rotate the qubit around the X(Y) axis by π/2 or π. The NV qubit is put on the equator of the Bloch sphere and rotated by the magnetic field generated by current flow. Pulses of different bias current are synced with the MW pulses such that the final signal is the difference between the two current flow patterns.

FIGS. 7A-7H show visualizations of Josephson current response to bias current and magnetic field. In FIG. 7A, the top schematic shows the measurement sequence that takes the difference between zero and finite current bias. The expected current flow shows changing line shapes at various bias current I_{bias}, with the opposite bias current leading to inverted current flow pattern around the center of the junction. FIGS. 7B-7C are maps showing the z-component of the current-generated magnetic field b_{z}. The arrows show the reconstructed current flow vector. Results are measured using the sequence shown in FIG. 7A, and the applied external magnetic field is B_{z}=0.95 mT. The SC electrodes are marked by solid lines and the normal metal part is marked by dashed lines. FIG. 7D shows a phase difference caused by bias current φ_{bias} extracted from the current flow profile at the junction. The result agrees with the sinusoidal current-phase relation. The inset shows the measured j_{y}(x) at I_{bias}=I_{c}, and the fitting results using Equation 13. The data in the gray area is excluded in the fitting. In FIG. 7E, the top schematic shows the measurement sequence that takes the difference between symmetric positive and negative I_{bias}. The expected signals change sign when measuring the 0-JV and 1-JV states at their respective |I_{c}|. All signals show cosine-like shapes, with amplitude growing with I_{bias}. FIGS. 7F-7G show b_{z} and current flow vector maps measured using the sequence shown in FIG. 7E. The Josephson current changes sign between 0-JV and 1-JV states. The external magnetic field is B_{z}=1.10 mT in FIG. 7F, and B_{z}=1.91 mT in FIG. 7G. FIG. 7H shows effective phase difference across the junction φ_{eff}=φₑl_{xmW/2} deviates from the external field contribution φₑₓₜ (indicated by the shaded area), as a result of induced phase from the Josephson current. The scale bar is 0.5 μm for FIGS. 7B-7C and 7F-7G. The measurements are taken at T=7 K. The error bars in FIG. 7D and FIG. 7H represent standard deviation from fitting.

FIGS. 8A-8F show electric control of JV ground state below critical current. FIG. 8A shows a differential resistance dV/dI measured in the same device as FIG. 6C but at T=4 K, showing an order-of-magnitude increase and oscillation of I_{c} that does not reach zero. The dashed box shows the measurement range in FIG. 8B. In FIG. 8B, the top schematic shows the measurement sequence. The main panel shows the differential magnetic field projected along NV axis [symbol] generated by the current flow response to the small ac current ĩ_{ac}≈0.8 ρA. [symbol] is shown versus DC bias current/ac and perpendicular magnetic field B_{z}. The NV is fixed at (x, y)≈(−500, 0)nm, where x=y=0 is the center of the Josephson junction. The circles are critical current extracted from transport result in FIG. 8A. FIG. 8C shows the difference of Gibbs free energy between the 0-JV and 1-JV states below I_{c}, Δε=ε_{0V}−ε_{1V}, from TDGL simulations. Labelled circles show simulated critical current of state with 0-(1-)JV. The shading in the non-overlap region is saturated to indicate only 0-JV and 1-JV state is present. FIGS. 8D-8E show spatial maps of differential [symbol] and current flow vector measured with sequence shown in FIG. 8B, showing both (FIG. 8D) 0-JV, and (FIG. 8E) 1-JV states at the same external field B_{z}=1.4 mT. The features in FIG. 8E are positioned asymmetrically because the JV is at right-of-center of the junction due to finite/ae. FIG. 8F shows a full vortex profile is observed when using a sequence that takes the difference between 0- and 1-JV states.

FIGS. 9A-9F show a new mechanism for the Josephson diode effect. In FIG. 9A, the left axis shows forward and backward critical current extracted from results measured in FIG. 8A. The right axis shows asymmetry parameter η showing JDE when time-reversal symmetry is broken by B_{z}. FIG. 9B shows schematics showing that inversion symmetry breaking (non-uniform J_{c}) at the junction can lead to different forward and backward critical current. FIGS. 9C-9D show that the differential magnetic field [symbol] and current flow vectors measured at symmetric ±I_{bias} show inversion asymmetric patterns. Measurements are taken at B_{z}=0.5 mT, using the same sequence as described with reference to FIG. 8B. FIGS. 9E-9F show simulated results corresponding to FIG. 9C and FIG. 9E, when inversion symmetry at the junction is broken, modeled as non-uniform junction width W₁>W₂. The measurements in (FIGS. 9A, 9C, 9D) are taken at T=4 K.

FIGS. 10A-10F show the evolution of Josephson current profile with external magnetic flux. FIG. 10A is a schematic of Josephson current flow for Φ_{z}=4Φ₀. Arrows on the device indicate how the current flows for I_{bias}=0. FIG. 10B shows a line cut of J_{y} at the junction with various fields from zero-flux to $2=400. Shaded area indicates a JV. I_{bias}=+|I_{c}| (FIGS. 10C, 10E) and fI_{bias}=0 (FIG. 10D) current flow for different magnetic flux values. FIGS. 10C-10D show fluxes between 0 to 1Φ₀ and FIGS. 10E-10F show fluxes between 1 to 2Φ₀.

FIGS. 11A-11D show extracting a SC phase difference φ_{bias} from a current profile measured at different I_{bias}. The current flow profile at the center of the JJ measured using the finite to zero bias current sequence, as described in FIGS. 7B-7C. The grey areas which correspond to regions closer to the JJ edge by the stand-off distance of the NV (≈180 nm), are excluded from the fitting. The bias current in each panel is (FIG. 11A) −I_{c}, (FIG. 11B) −0.75·I_{c}, (FIG. 11C) 0.75·I_{c} and (FIG. 11D) I_{c}. The circles represent the reconstructed j_{y} at the junction, and the lines represent the fit using sinusoidal current-phase relation and φ_{bias} as fitting parameter. The extracted φ_{bias} is shown in FIG. 7D.

FIGS. 12A-12J show Josephson current flow at various magnetic flux around B_{z}=B₀. FIGS. 12A-12E show the spatial maps of current flow and z-direction magnetic field measured using symmetric ±I_{bias} sequence as FIGS. 7F-7G, at external field values as shown by the labels above. FIGS. 12A-12C are B_{z}<B₀ and 0-JV; FIGS. 12D-12E are B_{z}>B₀ and 1-JV. The Josephson current flow switches sign from 0- to 1-JV. FIG. 12A and FIG. 12E are the same as FIGS. 7F-7G. The bias current used during the measurement in (FIG. 12A) I_{bias}/I_{c}≈0.7; (FIG. 12B) I_{bias}/I_{c}≈0.7; (FIG. 12C) I_{bias}/I_{c}≈0.9; (FIG. 12D) I_{bias}/I_{c}≈0.6; (FIG. 12E) I_{bias}/I_{c}≈0.8. It is emphasized that the normalized shape of j_{y} is not expected to depend on I_{bias}/I_{c}. So the result presented in FIGS. 7F-7G is insensitive to the exact value of I_{bias}/I_{c}. In FIGS. 12F-12J, circles show the reconstructed current flow at the center of JJ extracted from FIGS. 12A-12E, and the lines show the fitting to extract effective magnetic field B_{z, eff}, as shown in FIG. 7H. The dashed line in FIG. 12F shows that the j_{y}(x) profile expected from the φₑₓₜ induced by the external field, which does not match the presented measurement. The solid lines show the fitting results to extract φ_{eff}. The grey areas which corresponds to regions closer to the JJ edge by the stand-off distance of the NV (≈150 nm), are excluded from the fitting.

FIGS. 13A-13C show additional measurements using a symmetric bias ±I_{bias} sequence. FIGS. 13A-13B show spatial maps of current flow and z-direction magnetic field measured at the same external B_{z} as FIGS. 7F-7G but using I_{bias}=0.5l, instead of I_{c}. Here, shading scales with half the range, and the quiver with double the length per unit current density are used as in FIGS. 7F-7G. The shape of the current flow is almost the same, while the amplitude is half of those in FIGS. 7F-7G. The measurement is done at T=7 K. FIG. 13C, shows the current flow and b_{z} line cut from FIG. 7G. The jₓ(y) line trace along the vertical direction shows the JV extends into the SC electrodes by δW≈350 nm, making the effective area of the junction A=LW′, where W′=W+2δW≈850 nm. This is consistent with the effective area L²/1.842.

FIGS. 14A-14B show current flow for 2-JV state. FIG. 14A shows spatial maps of current flow and z-direction magnetic field measured using the symmetric ±I_{bias} sequence as FIGS. 7F-7G, measured at B_{z}≈4 mT and T=7 K. b, Line cut of current flow at the center of the JJ showing cosine-like current profile with twice the oscillations as in FIG. 7G, indicating 2 JVs at the junction. The circles show the reconstructed current value, the line is a guide for the eye connecting the circles.

FIG. 15 is an optical image of the JJ device. The SC electrodes made with NbN are false shaded. The RF line is used to deliver the microwave pulses to manipulate the NV. The Scale bar is 5 μm.

FIG. 16 shows temperature dependence of the critical current at zero magnetic field and a fitted curve for a diffusive junction.

FIGS. 17A-17D show the two-junction model. FIG. 17A is a schematic drawing of the model, showing left (right) JJs with critical current of J₁₍₂₎ forming a loop. The total phase difference between the JJs comes from the external magnetic field fₑₓₜ, and the Josephson current induced phase f_{cip}. FIGS. 17B-17D show a numerical simulation of forward/backward critical current

$${I}_{c}^{\pm } ,$$

and asymmetric parameter

$$η = \frac{\vert {I}_{c}^{+} \vert - \vert {I}_{c}^{-} \vert}{\vert {I}_{c}^{+} \vert + \vert {I}_{c}^{-} \vert}$$

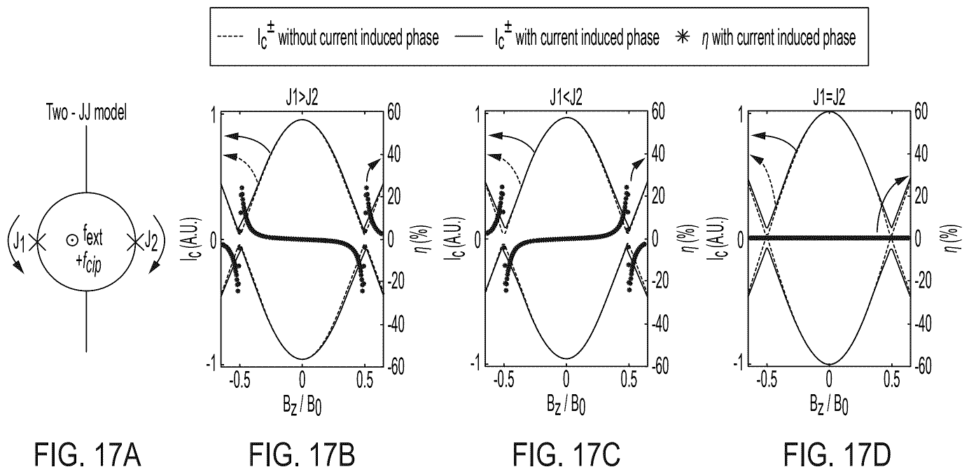

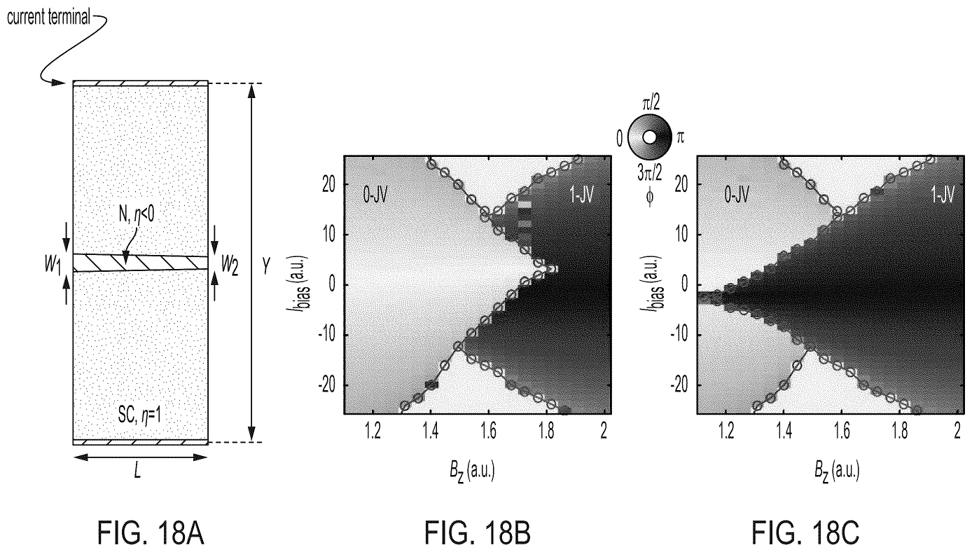

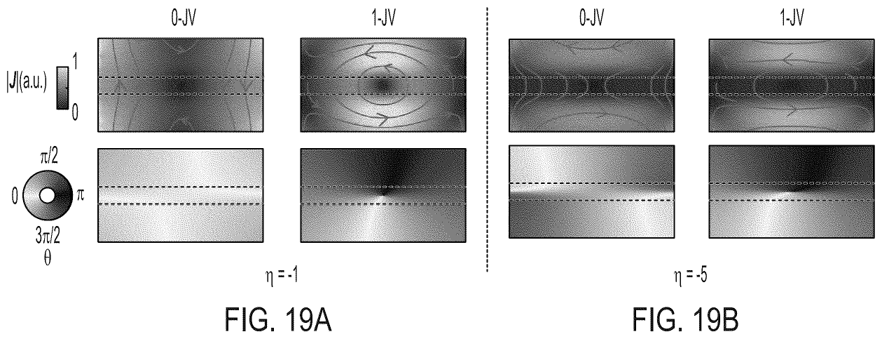

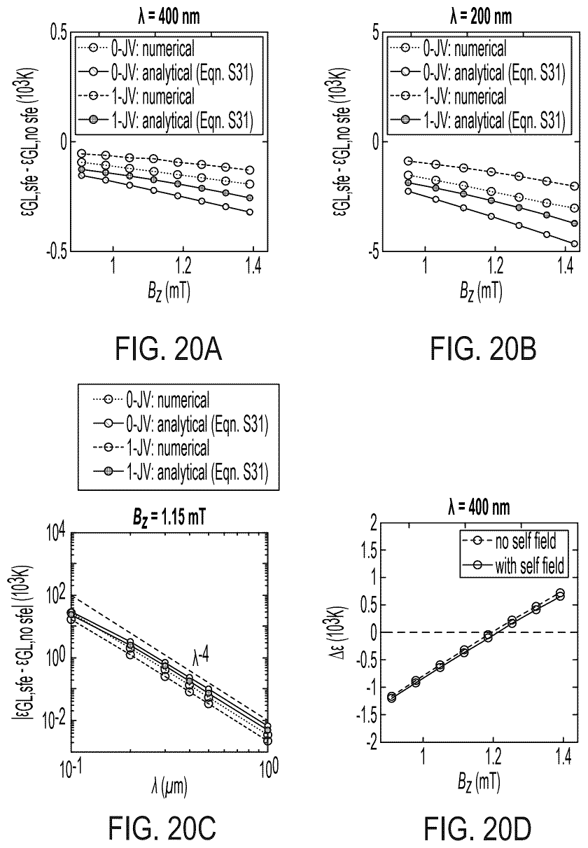

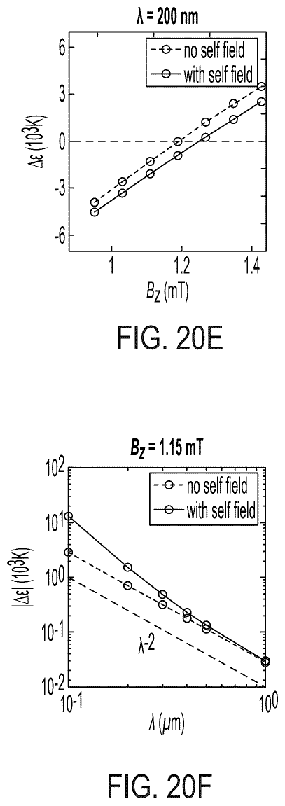

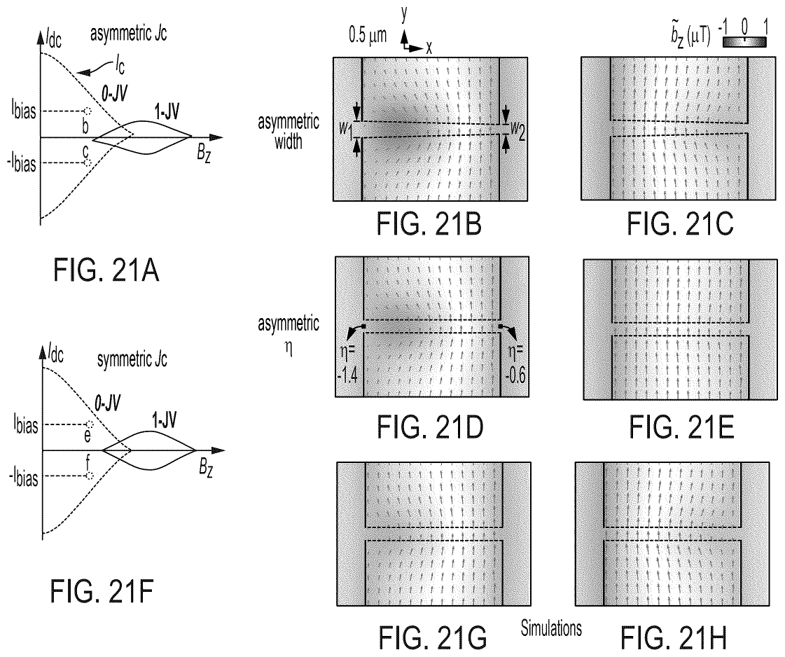

as a function of external flux when (FIG. 17A) J₁>J₂, (FIG. 17C) J₁<J₂ and (FIG. 17D) J₁=J₂. In FIG. 17B and FIG. 17C, the difference between J_{1,2} is 10%. Solid (Dashed) lines show the critical current I_{c} calculated with (without) the current induced phase. Stars show the asymmetric factor η when the current flow induced phase is included. In the inversion symmetric case (FIG. 17D), there is no diode effect. In the inversion symmetry broken cases J₁≠J₂ in FIGS. 17B and 17C, the diode effect is present when the current induced phase is included. η changes sign for J₁ larger or smaller than J₂.

FIGS. 18A-18C show a TDGL simulation schematic and initial conditions. FIG. 18A is a schematic drawing of the simulated device. The drawing is not to scale so as to highlight the junction area in the middle of the device. FIGS. 18B-18C show phase differences across the junction for the (FIG. 18V) 0-JV and (FIG. 18C) 1-JV states. The circles mark the critical current for the two solutions. The result beyond the critical current is blanked for clarity.

FIGS. 19A-19B show varying critical currents with n of the normal region. FIGS. 19A-19B show simulated local current density and superconducting phase using (FIG. 19A) η=−1 and (FIG. 19B) η=−5 for the normal area of the junction. The simulations here are done in a symmetric junction for clarity, with W₁=W₂=150 nm. All cases are simulated at the same external magnetic field, at zero bias, and neglecting the self-field effect.

FIGS. 20A-20F show the energy difference of solutions with or without coupling to the self-field versus the external magnetic field B_{z}. Results are taken at (FIG. 20A) λ=400 nm, and (FIG. 20B) λ=200 nm. The top two (bottom two) points in the legend represent the 0-(1-) JV states. The open points are numerical results obtained by iterating both Y′ and FIG. 20A. The filled points are results given by an approximate analytical formula, where the energy shift from coupling to the self-field is the negative of the 3D magnetic field energy. FIG. 20C shows the absolute value of the energy difference of solutions with or without coupling to the self-field, plotted versus of A. In particular, the energy difference is the magnetic field energy which is expected to scale with 1-4 (shown by the dashed line as a guide for the eye). FIGS. 20D-20E show energy difference of the 0-JV and 1-JV states Δε=ε₀−ε₁ if the self field effect is included for (FIG. 20D) λ=400 nm, and (FIG. 20E) λ=200 nm. Smaller λ represents a larger self-field effect. FIG. 20F shows |Δε| as a function of λ at fixed external magnetic field. The total energy difference between 0-JV and 1-JV states without coupling to the self-field is expected to scale with λ⁻² (shown by the dashed line as a guide for the eye). FIGS. 20C and 20F are simulated at B_{z}=1.15 mT. The simulations are done in a symmetric Josephson junction with W₁=W₂=150 nm, and the external DC bias is zero.

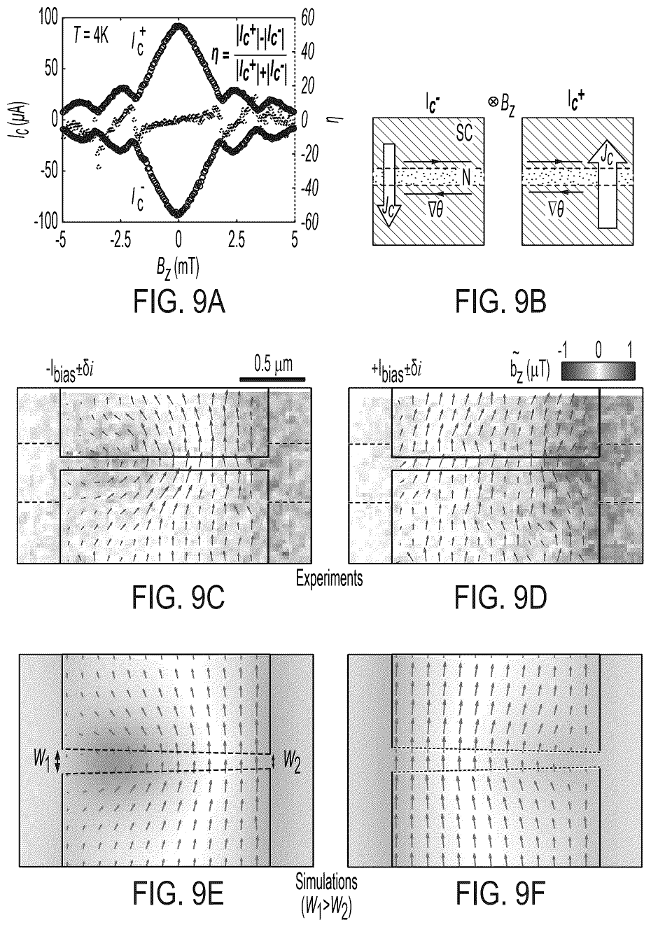

FIGS. 21A-21H show TDGL simulations on JJs with symmetric or asymmetric geometry. FIGS. 21A and 21F are schematic drawings of the critical current of 0-JV and 1-JV states versus external magnetic field B_{z}, for (FIG. 21A) inversion-asymmetric, and (FIG. 21F) inversion-symmetric junctions. FIGS. 21B-21E show simulated current flow and the z-direction of magnetic field from a differential measurement. The maps are taken in an asymmetric JJ with non-uniform critical current density along the x direction. FIGS. 21B-21C are simulated with tilted junction width W₁>W₂. FIGS. 21D-21E are simulated with non-uniform n factor in the normal region (η changes linearly with x from −1.4 to −0.6). The DC bias current are symmetric with zero as shown in FIG. 21A. FIGS. 21B-21C are the same as FIGS. 9E-9F. FIGS. 21G-21H show simulated current flow and z-direction of magnetic field from a symmetric JJ with uniform critical current density along x direction. The DC bias currents are shown in FIG. 21F. Current flow is inversion symmetric for ±I_{bias} when inversion symmetry of the JJ is preserved.

### DETAILED DESCRIPTION

Conventional diodes, which permit classical current flow in one direction and restrict flow in the other, are a ubiquitous feature of modern circuit and computing design, with wide-ranging applications including but not limited to logic gates, signal rectification, and detector construction. In contrast, superconducting diodes exhibit asymmetric superconductive behavior during operation in which superconductive current (e.g., current experiencing zero electrical resistance, or “supercurrent”) is permitted to flow in one direction while classical current (e.g., current experiencing a finite resistance) is permitted to flow in the other direction. As a fundamental circuit element analogous to conventional diodes, superconducting diodes are envisioned for a number of applications, including but not limited to high-speed electronics, dissipationless electronics, single photon detectors, and quantum computers. Superconducting diodes may therefore serve as an important building block for the continued development of nascent technologies.

As one example, superconducting diodes have been developed which utilize the Josephson effect, a macroscopic quantum phenomenon in which supercurrent flows through adjacent superconductors despite a barrier—for example, a piece of non-superconducting material—separating the adjacent superconductors. The supercurrent is able to flow because of quantum tunneling, which permits the electrons to pass through the barrier without resistance, even though classical physics would not predict supercurrent flow in such a structure. The Josephson effect can be leveraged to construct a superconducting diode, or “Josephson diode,” in situations in which the time reversal symmetry and inversion symmetry of the device are broken by the application of external magnetic fields. However, reliance on external magnetic fields can limit the scalability of devices integrating the superconducting diode and also may cause the superconducting diode to be incompatible with certain superconducting circuits (e.g., by reducing or interfering with the functionality of the circuits, as is the case with superconducting quantum computer circuits).

While superconducting diodes which do not utilize the application of external magnetic fields have been studied, these superconducting diodes have generally been implemented using only specialized heterostructures which may necessitate complicated manufacturing processes. Additionally, because in such heterostructures the diode functionality is inherent to the structure of the device, the properties of such a superconducting diode cannot be easily adjusted during operation of the diode.

The inventors have recognized and appreciated that known superconducting diode devices are conventionally difficult to operate, do not integrate with other superconducting circuitry, or can require complex manufacturing processes such that the current applicability of superconducting diodes is limited. The inventors have further recognized and appreciated properties of superconducting junctions which permit the development of novel superconducting diodes. For example, inversion symmetry can be broken in a junction device by fabricating the junction with an asymmetry (e.g., a structural or material asymmetry which causes a spatial asymmetry in the critical current of the junction). Additionally, time-reversal symmetry can be broken without the use of an external magnetic field by introducing a current which is at least partially transverse to a length of the junction and to a bias current through the device, because this transverse current creates a phase gradient along the transverse current path and therefore along the length of the junction. The inventors have further recognized and appreciated a Josephson current-induced phase effect which may be strong in thin film superconductors with low superfluid density and high kinetic inductance.

Accordingly, the inventors have developed techniques which allow for the manufacture and operation of superconducting diodes using applied electrical signals. Significantly, this allows for the operation of a superconducting diode without the application of an external magnetic field, although such a field is not incompatible with embodiments described herein. Additionally, because the diode functionality is a function of the electrical signals applied to the device as well as of the structure thereof, the diode functionality may be dynamically adjusted according to operational requirements. Further, because the techniques described herein do not depend on properties of particular superconducting materials, they may readily be applied to a wide range of superconductors, from the well-understood to the highly novel, and including both conventional and high-temperature superconducting materials.

In some embodiments, the superconducting diodes described herein include a junction device having a first superconducting portion and a second superconducting portion. The first and second superconducting portions are separated by an asymmetric junction. An asymmetric junction is a junction (e.g., a Josephson junction, Dayem bridge, or other superconducting junction structure) having a critical current that is spatially asymmetric. For example, the junction may be geometrically asymmetric (e.g., having different junction widths or notch sizes) or may be materially asymmetric (e.g., being formed of different non-superconducting materials at different positions along the junction). Additionally, the superconducting diode includes a transverse superconducting electrode coupled to the first superconducting portion. In some embodiments, a transverse superconducting electrode may additionally or alternatively be coupled to the second superconducting portion.

In some embodiments, during operation of the superconducting diode, a bias current is applied to the first superconducting portion. Additionally, a transverse current is applied to the transverse superconducting electrode, which causes the junction device to act as a superconducting diode. In some embodiments, the polarity of the superconducting diode may be controlled by selecting a direction of the applied transverse current, and/or the efficiency of the superconducting diode may be controlled by selecting a magnitude of the applied transverse current.

Following below are more detailed descriptions of various concepts related to, and embodiments of, creation and control of superconducting diodes using electrical signals. It should be appreciated that various aspects described herein may be implemented in any of numerous ways. Examples of specific implementations are provided herein for illustrative purposes only. In addition, the various aspects described in the embodiments below may be used alone or in any combinations and are not limited to the combinations explicitly described herein.

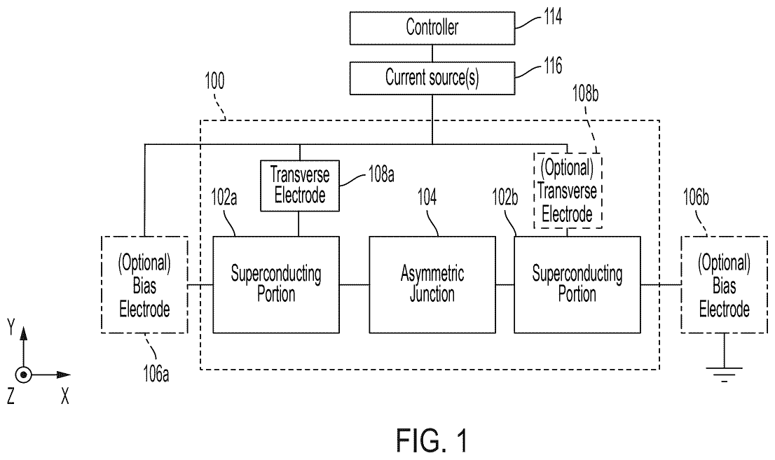

FIG. 1 is a schematic diagram of an example of a superconducting diode 100 and optional supporting components, according to some embodiments of the technology described herein. The superconducting diode 100 includes a first superconducting portion 102a, a second superconducting portion 102b, an asymmetric junction 104, and a transverse electrode 108a coupled to the first superconducting portion 102a. As depicted in the example of FIG. 1, the superconducting diode 100 may optionally include another transverse electrode 108b coupled to the second superconducting portion 102b. It should be appreciated that, in some embodiments, the superconducting diode 100 may include one or both of transverse electrode 108a and transverse electrode 108b, as aspects of the technology described herein are not limited in this aspect.

Though not depicted in the example of FIG. 1, one or more components of the superconducting diode 100 may be formed on a suitable planar substrate (e.g., formed of undoped silicon, silicon dioxide, sapphire, or other suitable substrate materials) using suitable microfabrication techniques including but not limited to lithography (e.g., photolithography, electron-beam lithography), material deposition (e.g., using evaporation, sputtering, molecular beam epitaxy (MBE) fabrication, atomic layer deposition (ALD), and/or chemical vapor deposition (CVD) techniques), and/or material etching (e.g., reactive ion etching (RIE), sputter etching, and/or ion beam etching (IBE) techniques).

In some embodiments, the first superconducting portion 102a and the second superconducting portion 102b may be thin films formed of a suitable superconducting material. As used herein, “thickness” describes a dimension in a direction substantially perpendicular to a plane of the surface of the substrate supporting the components of the superconducting diode 100, as indicated by the Z-direction in the example of FIG. 1. For example, the first superconducting portion 102a and the second superconducting portion 102b may have a thickness of less than 100 nm, of less than 50 nm, and/or of less than 25 nm. In some embodiments, the thickness of the first superconducting portion 102a and the second superconducting portion 102b may be approximately 20 nm. For embodiments in which the first superconducting portion 102a and/or second superconducting portion 102b are formed of van der Waals superconductors (e.g., NbSe₂, Bi₂Sr₂CaCu₂O_{8+δ} (BSSCO), etc.), the thickness of the first superconducting portion 102a and the second superconducting portion 102b may be as thin as a single atomic layer. In some embodiments, the first superconducting portion 102a and/or the second superconducting portion 102b may have a thickness that is selected such that, during operation of the superconducting diode 100, the application of a transverse current (e.g., from transverse electrode 108a and/or 108b) can be used to control the properties of the resulting diode.

In some embodiments, the first superconducting portion 102a and the second superconducting portion 102b may have a width selected based on dimensional and operational requirements of a device in which the superconducting diode is integrated. As used herein, “width” describes a dimension substantially parallel to the Y-direction in the examples of FIGS. 1-3C herein. In some embodiments, the first superconducting portion 102a and/or second superconducting portion 102b may have a width of 200 nm. In some embodiments, the width of the first superconducting portion 102a and/or the second superconducting portion 102b may be less than 1 nm, less than 100 nm, less than 250 nm, less than 500 nm, less than 1 μm, less than 2 μm, and/or less than 5 μm. In some embodiments, the minimum width of the first superconducting portion 102a and/or the second superconducting portion 102b may be governed by the capabilities of state-of-the-art lithography technology and the maximum width may be governed by dimensional requirements of a device and/or circuit in which the superconducting diode is integrated, though it is understood that the width of the superconducting portions may impact an efficiency of the superconducting diode as well as the critical current of the superconducting portions. In some embodiments, the maximum width may be governed by a coherence length in a proximitized superconducting region.

The first superconducting portion 102a and the second superconducting portion 102b may be formed of any suitable superconducting material, including but not limited to elemental superconductors (e.g., lead, aluminum, niobium), alloys (e.g., niobium titanium (NbTi), germanium niobium (Nb₃Gc), and/or niobium nitride (NbN)), and/or ceramics (e.g., magnesium diboride (MgB₂)). In some embodiments, the first superconducting portion 102a and/or second superconducting portion 102b may be formed of van der Waals superconductors including but not limited to bismuth strontium calcium copper oxide (BSCCO). Because the effects being leveraged are not dependent on the critical temperature of the selected superconducting materials, the first superconducting portion 102a and/or second superconducting portion 102b may be alternatively or additionally be formed of high temperature superconducting (HTS) materials including but not limited to BSCCO, yttrium barium copper oxide (YBCO), thallium barium calcium copper oxide (TBCCO), and/or mercury barium calcium copper oxide (HBCCO). Additionally, it should be appreciated that in some embodiments, the first superconducting portion 102a may include different materials from the second superconducting portion 102b, as aspects of the technology described herein are not limited in this respect.

In some embodiments, the asymmetric junction 104 is disposed between the first superconducting portion 102a and the second superconducting portion 102b such that the asymmetric junction 104 separates the first superconducting portion 102a from the second superconducting portion 102b (e.g., thereby forming a tunneling junction). The asymmetric junction 104 may separate the first superconducting portion 102a from the second superconducting portion 102b by any suitable distance at which the Josephson effect may occur, ranging from less than one nanometer to approximately one micrometer. For example, the asymmetric junction 104 may separate the superconducting portion 102a and the second superconducting portion 102b by a distance of 1 nm, less than 10 nm, less than 100 nm, 200 nm, less than 250 nm, less than 500 nm, less than 750 nm, and/or less than 1 μm. In some embodiments, the asymmetric junction 104 may separate the superconducting portion 102a and the second superconducting portion 102b by a distance of one micrometer. In some embodiments, the minimum separation distance of first superconducting portion 102a and the second superconducting portion 102b may be governed by the capabilities of state-of-the-art lithography technology, and the maximum separation distance may be governed by an upper limit at which the superconducting diode 100 will cease to be superconducting.

In some embodiments, the asymmetric junction 104 is “asymmetric” due to a changing (e.g., cither continuously or discretely) critical current along the width of the asymmetric junction 104 (i.e., along a direction substantially parallel to the Y-direction). In some embodiments, the asymmetrical critical current value may be caused by geometrical asymmetry of the asymmetric junction 104, including but not limited to one portion of the asymmetric junction 104 having different dimensions than another portion of the asymmetric junction 104. In some embodiments, the asymmetrical critical current value may be caused by material asymmetries, including but not limited to one portion of the asymmetric junction 104 having a different material composition than another portion of the asymmetric junction 104.

In some embodiments, the asymmetric junction 104 may be a Josephson junction and may be formed of a thin film separating the first superconducting portion 102a and the second superconducting portion 102b. The thin film junction may be formed of a material having a finite resistance at an operational temperature of the superconducting diode (e.g., below a critical temperature or temperatures of the superconducting material(s) used to form the first superconducting portion 102a and the second superconducting portion 102b). As one example, the asymmetric junction 104 may include a metal thin film (e.g., gold, copper). As an alternative example, the asymmetric junction 104 may include a conventional insulator. The material of the asymmetric junction 104 may impact the performance of the superconducting diode 100 in that different materials may have different “transparency,” which dictates the distance over which the Josephson effect may be permitted.

In some embodiments, the asymmetric junction 104 may include a Dayem bridge. A Dayem bridge is a structure that creates a narrow constriction between the first superconducting portion 102a and the second superconducting portion 102b. For example, the Dayem bridge may be formed of a wire structure and/or a “notch” structure. Such a notch may have a first edge which extends parallel to edges of the first superconducting portion 102a and the second superconducting portion 102b and two sloping, opposing edges which slope inwardly towards the first edge and meet at a vertex. The vertex may be sharp or rounded, in some embodiments.

In some embodiments, the superconducting diode 100 includes a transverse electrode 108a coupled to the first superconducting portion 102a. In some embodiments, the superconducting diode 100 may additionally or alternatively include a transverse electrode 108b coupled to the second superconducting portion 102b. During operation of the superconducting diode 100, a current may be applied to the transverse electrode 108a (e.g., by one or more current sources 116) causing a transverse current to flow through the first superconducting portion 102a (e.g., in a direction substantially parallel to the Y-direction of FIG. 1). In embodiments including transverse electrode 108b, during operation of the superconducting diode 100, a current may additionally or alternatively be applied to the transverse electrode 108b, thereby causing a transverse current to flow through the second superconducting portion 102b.

In some embodiments, the transverse electrode 108a and/or transverse electrode 108b may be positioned at a distance along the X-direction relative to the asymmetric junction 104 such that the transverse current generated during operation of the superconducting diode 100 is oriented adequately relative to the asymmetric junction 104a. That is, the transverse electrode 108a and/or transverse electrode 108b are preferably positioned near enough to the asymmetric junction 104 such that the transverse current serves to break time-reversal symmetry, but the transverse electrode 108a and/or transverse electrode 108b are not positioned so distant from the asymmetric junction 104 that the desired transverse current is entirely subsumed in the applied bias current. For example, in some embodiments, the transverse electrode 108a and/or transverse electrode 108b may be a distance of less than or approximately equal to one micrometer from the asymmetric junction 104 along the X-direction. In some embodiments, the transverse electrode 108a and/or transverse electrode 108b may be a distance of less than 10 nm, less than 100 nm, less than 250 nm, less than 500 nm, less than 750 nm, less than 1 μm, less than 2 μm, and/or less than 3 μm from the asymmetric junction along the X-direction. In some embodiments, the distance from the transverse electrode 108a and/or transverse electrode 108b to the asymmetric junction 104 may be governed by the capabilities of state-of-the-art lithography technology The transverse electrode 108a and/or transverse electrode 108b may have a typical size along the X-direction of approximately 100 nm and a minimum size governed by state-of-the-art manufacturing capabilities. In some embodiments, the transverse electrode 108a and/or transverse electrode 108b may have a size along the X-direction of less than 5 nm, less than 10 nm, less than 50 nm, less than 100 nm, less than 250 nm, less than 500 nm, less than 750 nm, less than 1 μm, less than 2 μm, and/or less than 3 μm.

In some embodiments, the transverse electrode 108a and/or transverse electrode 108b may be formed of the same superconducting materials as respective first superconducting portion 102a and/or second superconducting portion 102b. For example, the transverse electrode 108a and/or transverse electrode 108b may be fabricated at a same time as the respective first superconducting portion 102a and/or second superconducting portion 102b by simultaneous lithographic patterning of the coupled components and simultaneous deposition of the superconducting material forming the coupled components. However, it should be understood that the first superconducting portion 102a and second superconducting portion 102b may be formed of different superconducting materials than the transverse electrode 108a and/or transverse electrode 108b, as aspects of the technology described herein are not limited in this respect.

In some embodiments, and as illustrated in FIG. 1, the superconducting diode 100 may be coupled to additional components to support operation of the superconducting diode 100. For example, optional bias electrodes 106a and/or 106b may be coupled to first superconducting portion 102a and/or second superconducting portion 102b to permit electrical coupling of the superconducting diode 100 to one or more current source(s) 116. The current source(s) 116 may also be coupled to transverse electrode 108a and/or transverse electrode 108b, and a controller 114 may be coupled to one or more current source(s) 116 to enable control of the application of electrical signals to the superconducting diode 100. It should be appreciated that the superconducting diode 100 may be coupled to external devices in any suitable fashion, as the technology described herein is not limited to the illustrative arrangement of FIG. 1. For example, the first superconducting portion 102a, second superconducting portion 102b, and/or transverse electrodes 108a, 108b may be coupled to other circuitry components (e.g., to other superconducting diodes or other circuitry components) when the superconducting diode 100 is integrated into superconducting circuit devices.

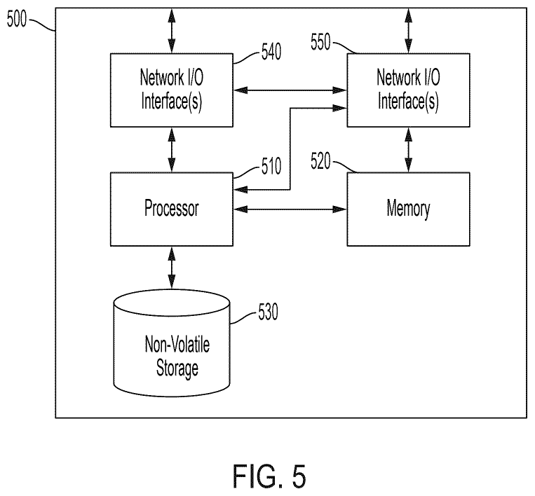

In some embodiments, the controller 114 may be configured to control the operation of the superconducting diode 100 and/or an apparatus in which the superconducting diode 100 is integrated. The controller 114 may include a computer system and/or hardware circuitry (e.g., as described herein with reference to FIG. 5). The controller 114 may include hardware and/or software elements and may be configured to be operated manually and/or to operate automatically.

In some embodiments, the controller may be coupled to one or more current source(s) 116, and may be configured to, during the operation of the superconducting diode 100, cause the application of a bias current to the first superconducting portion 102a (e.g., by applying a current to first superconducting portion 102a directly or indirectly such as through optional bias electrodes 106a and/or 106b). As shown in the example of FIG. 1, in some embodiments, a first bias electrode 106a may be coupled to the first superconducting portion 102a and a second bias electrode 106b may be coupled to the second superconducting portion 102b. The first bias electrode 106a and the second bias electrode 106b may be arranged to permit a bias current to flow from the first superconducting portion 102a, across the asymmetric junction 104, and through the second superconducting portion 102b.

As shown in the example of FIG. 1, the first bias electrode 106a may be coupled to the one or more current source(s) 116 and the second bias electrode 106b may be coupled to ground such that, during operation of the superconducting diode 100, the bias current flows from the first superconducting portion 102a to the second superconducting portion 102b. However, it should be appreciated that first bias electrode 106a may alternatively be coupled to ground and second bias electrode 106b may be coupled to one or more current source(s) 116 such that the bias current is configured to flow from second superconducting portion 102b to first superconducting portion 102a, as aspects of the technology described herein are not limited in this respect. Additionally, it should be appreciated that in some embodiments, the first bias electrode 106a and/or second bias electrode 106b may not be present such that the first superconducting portion 102a and/or the second superconducting portion 102b are directly electrically coupled to the one or more current source(s) 116 or to ground, as aspects of the technology described herein are not limited in this respect.

In some embodiments, the controller may also be configured to, during operation of the superconducting diode 100, cause the application of a transverse current to the transverse electrode 108a and/or to the transverse electrode 108b. For example, the transverse electrode 108a and/or the transverse electrode 108b may be coupled to the one or more current source(s) 116 such that the transverse current is configured to flow, for example, from the transverse electrode 108a, through the first superconducting portion 102a, across asymmetric junction 104, through the second superconducting portion 102b, and through the transverse electrode 108b and/or the bias electrode 106b. The transverse current may be any suitable magnitude such that a total current density (e.g., considering the bias current and the transverse current) in the superconducting diode 100 does not exceed a critical current of the superconducting diode 100 (e.g., as dependent on the critical current of components such as the superconducting portions and the asymmetric junction 104).

A direction of the transverse current may determine, or influence, a polarity of the superconducting diode 100. For example, a transverse current flowing through the transverse electrode 108a towards the second superconducting portion 102b may cause the superconducting diode 100 to permit a supercurrent cross the superconducting diode 100 in the direction from the first superconducting portion 102a to the second superconducting portion 102b while permitting only a conventional current from the second superconducting portion 102b to the first superconducting portion 102a. Conversely, a transverse current in the opposite direction (e.g., towards rather than from the transverse electrode 108a and/or from rather than to the transverse electrode 108b) may cause the superconducting diode 100 to permit supercurrent from the second superconducting portion 102b while permitting only a conventional current from the first superconducting portion 102a to the second superconducting portion 102b.

A magnitude of the transverse current may determine, or influence, an efficiency of the superconducting diode 100. The efficiency of the superconducting diode 100 may be indicative of the asymmetry of directional critical currents through the superconducting diode 100, with a higher efficiency corresponding to a high asymmetry which is desirable for many applications of such a superconducting diode. In some embodiments, a greater magnitude of transverse current may correspond to a greater efficiency of the superconducting diode 100. In some embodiments, a maximum efficiency may be achieved when a total current-induced phase along the transverse current is approximately, or 180 degrees. The current induced phase may be proportional to the product of a kinetic inductance of the superconducting portion 102a and/or the superconducting portion 102b and a density of supercurrent (e.g., resulting from the bias current and/or the transverse current) through the superconducting diode 100.

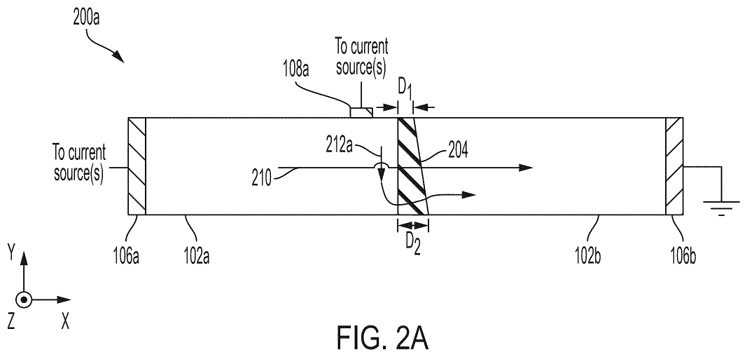

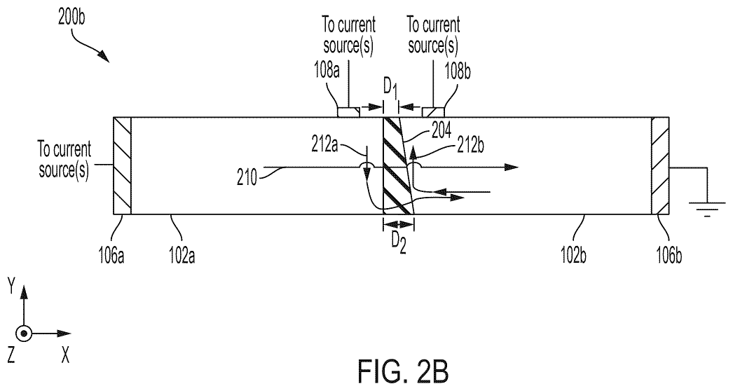

FIG. 2A is a schematic diagram of an illustrative superconducting diode 200a having an asymmetric Josephson junction 204 and a transverse electrode 108a, according to some embodiments. As shown in the example of FIG. 2A, the superconducting diode 200a includes the first superconducting portion 102a, the second superconducting portion 102b, and an asymmetric Josephson junction 204 separating the first superconducting portion 102a and the second superconducting portion 102b. The superconducting diode 200a also includes a transverse electrode 108a coupled to the first superconducting portion 102a. As illustrated in FIG. 2A, a first bias electrode 106a and a second bias electrode 106b, respectively coupled to the first superconducting portion 102a and the second superconducting portion 102b, are provided, though it should be appreciated that the first bias electrode 106a and the second bias electrode 106b are optional as described in connection with FIG. 1 herein. FIG. 2A also shows illustrative paths of flow of a bias current 210 and a transverse current 212a through the superconducting diode 200a. While no supporting circuitry (e.g., controller 114 or the one or more current source(s) 116) are depicted in FIG. 2A, it should be understood that such components may be present in an implementation of superconducting diode 200a.

In some embodiments, and as is illustrated in FIG. 2A, the asymmetric Josephson junction 204 exhibits a geometric asymmetry, with a narrower portion, having a gap distance D₁, of the asymmetric Josephson junction 204 disposed proximate to the transverse electrode 108a. The asymmetric Josephson junction 204 has a wider portion, having a gap distance D₂>D₁, disposed at a distal position across the first superconducting portion 102a from the transverse electrode 108a. In some embodiments, the width of the asymmetric Josephson junction 204 along the Y-direction may be larger than either of D₁ or D₂.

While the example of FIG. 2A illustrates the asymmetric Josephson junction 204 as having a continuous change in gap distance along the Y-direction, it should be appreciated that the asymmetric Josephson junction 204 may have discrete changes in gap distance (e.g., a stepwise change in gap distance) along the Y-direction, as aspects of the technology described herein are not limited in this respect.

In some embodiments, the geometric asymmetry of the asymmetric Josephson junction 204 causes the critical current of the asymmetric Josephson junction 204 to vary along the Y-direction. This spatial variation in the critical current removes inversion symmetry from the device structure, thereby causing, in conjunction with the application of a transverse current, the superconducting diode 200a to act as a diode during operation.

In some embodiments, and as illustrated in FIG. 2A, during operation of the superconducting diode 200a the bias current 210 may be configured to flow from the first superconducting portion 102a to the second superconducting portion 102b. Alternatively, in some embodiments, the bias current 210 may be configured to flow from the second superconducting portion 102b to the first superconducting portion 102a during operation of the superconducting diode 200a (e.g., by coupling the first bias electrode 106a to ground and coupling the second bias electrode 106b to a current source).

In some embodiments, the bias current 210 may be applied with a magnitude limited by the critical current density of the superconducting diode 200a. For example, the magnitude of the bias current 210 may be any magnitude at which the superconducting diode 200a remains superconducting, taking into consideration factors such as operating temperature, materials used to fabricate the superconducting diode 200a, and dimensions of the components of the superconducting diode 200a.

In some embodiments, the transverse current 212a may be configured to flow from or to a first transverse electrode 108a. Due to the asymmetry of the asymmetrical junction 204, the transverse current 212a may flow along a direction substantially orthogonal to the direction of the bias current 210 and/or along a direction substantially parallel to an interface between the first superconducting portion 102a and the asymmetric Josephson junction 204. The magnitude of transverse current may be used to tune an efficiency of the superconducting diode 200a, and the direction of transverse current 212a may be used to control a polarity of the superconducting diode 200a.

FIG. 2B is a schematic diagram of an illustrative superconducting diode 200b having an asymmetric Josephson junction 204 and a second transverse electrode 108b, according to some embodiments of the technology described herein. FIG. 2B differs from FIG. 2A in that superconducting diode 200b is illustrated as including a second transverse electrode 108b in addition to transverse electrode 108a. It should be appreciated, however, that in some embodiments the superconducting diode 200a or superconducting diode 200b may include only the transverse electrode 108b, as aspects of the technology described herein are not limited in this respect.

In some embodiments, applying a transverse current 212b in addition to or as an alternative to the transverse current 212a to the second transverse electrode 108b may alter the polarity and/or efficiency of the superconducting diode 200b. For example, the first transverse electrode 108a may be coupled to a current source and the second transverse electrode may be coupled to a current sink such that transverse current 212a flows in one direction along the asymmetric Josephson junction 204 and the transverse current 212b flows in an opposing direction along the opposing side of the asymmetric Josephson junction 204. By causing transverse currents 212a and 212b to flow along opposing sides of the asymmetric Josephson junction 204 with opposing directions, the polarity and/or efficiency of the superconducting diode 200b may be further enhanced as compared to a superconducting diode design including only a single transverse electrode 108a or 108b. It should be understood that the first transverse electrode 108a may alternatively be coupled to a current sink and the second transverse electrode 108b may be alternatively coupled to a current source, as aspects of the technology described herein are not limited in this respect, and that switching the directions of transverse current 212a and transverse current 212b may cause a reversal in the polarity of the superconducting diode 200b.

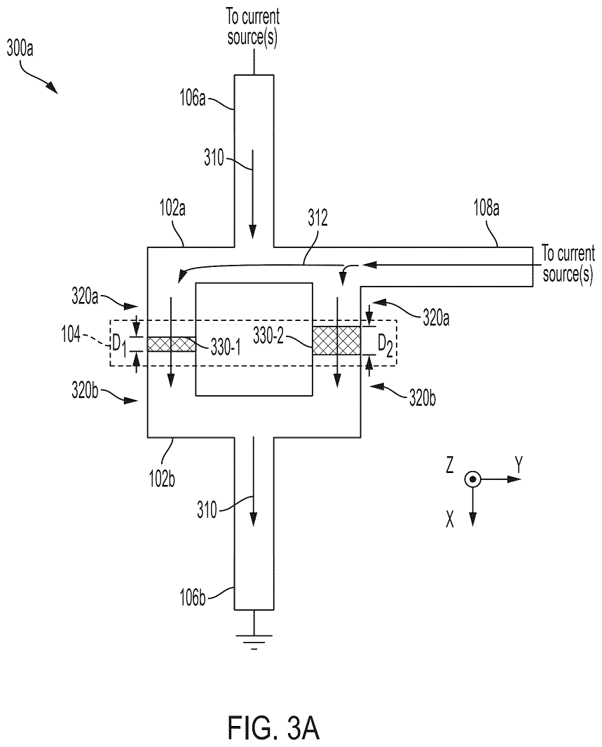

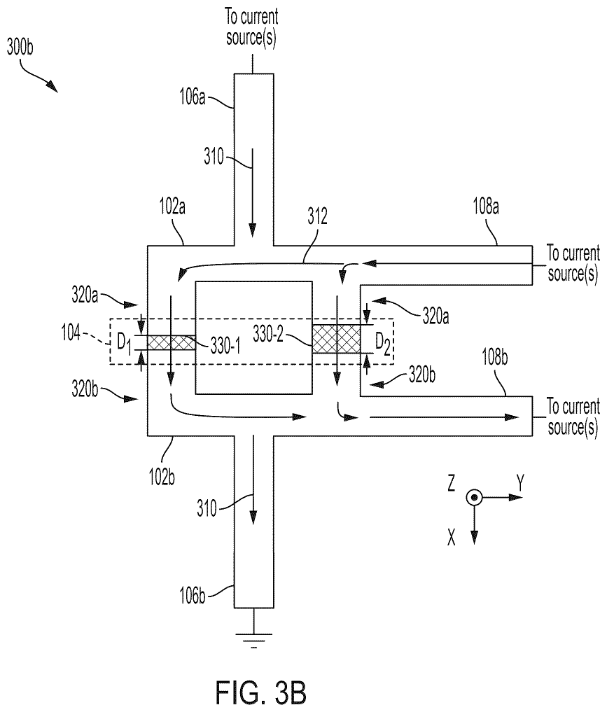

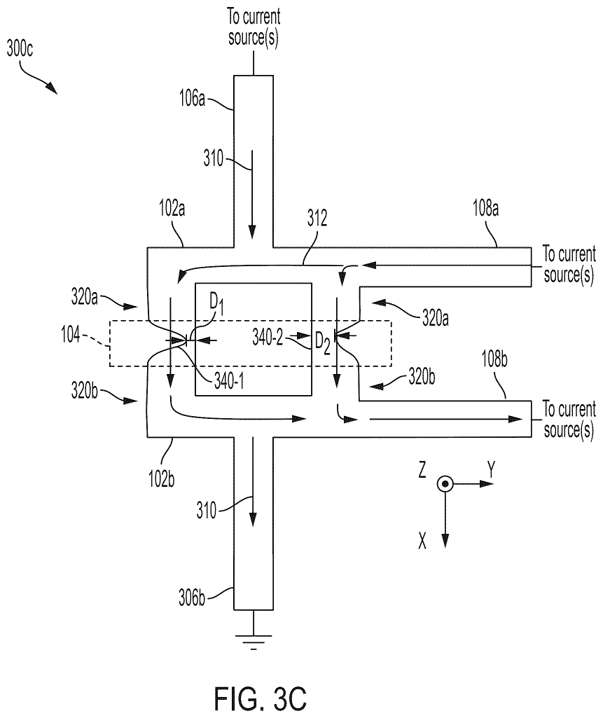

FIG. 3A is a schematic diagram of an illustrative superconducting diode 300a having multiple arms, each arm including an associated Josephson junction, and a transverse electrode, in accordance with some embodiments of the technology described herein. As shown in the example of FIG. 3A, the superconducting diode 300a includes a first superconducting portion 102a with arms 320a and a second superconducting portion 102b with respective arms 320b. In some embodiments, the arms 320a, 320b may be separated along the Y-direction by a distance in a range from 1 nm (e.g., as limited by state-of-the-art lithography resolution) to a maximum distance that permits the superconducting diode to remain superconducting during operation of the device.

While the example of FIG. 3A illustrates two arms associated with each superconducting portion 102a, 102b, it should be understood that the superconducting portions 102a, 102b may include two or more arms (e.g., three arms, four arms, five arms, between two and ten arms, between ten and 100 arms, or any suitable number of arms within these ranges). It should also be understood that while in many applications it may be desirable for each arm of one superconducting portion to be structurally and physically joined to a corresponding arm of the other superconducting portion by a junction, a superconducting diode with a plurality of arms need not have each arm structurally connected by a junction in order for the diode to function. Thus, in embodiments with a plurality of arms, not every arm need be physically connected by a junction to a corresponding arm in order for the diode to function, and any junction which permits the Josephson effect to occur may be said to connect corresponding arms.

In some embodiments, the asymmetric junction 104 may include multiple junctions, each junction being disposed between respective ones of the arms 320a and 320b. As illustrated in the example of FIG. 3A, asymmetric junction 104 includes a first junction 330-1 and a second junction 330-2. In some embodiments, each junction forming the asymmetric junction 104 may be characterized with a different critical current, thereby causing the desired asymmetry of asymmetric junction 104.

In some embodiments, and as illustrated in the example of FIG. 3A, the junctions 330-1 and 330-2 are Josephson junctions with a different gap distance separating the respective ones of the arms 320a and 320b (e.g., separating the superconducting portions 102a and 102b with a material having a finite resistance at the operational temperature of the superconducting diode 300a). In particular, junction 330-1 has a gap distance of D₁, and junction 330-2 has a gap distance of D₂>D₁. It should be appreciated that in embodiments having three or more junctions that each of the three or more junctions may have differing gap distances (e.g., D₁≠D₂≠D₃), though a diode effect may be observed with at least one gap distance not equal to the others (e.g., D₁=D₂≠D₃ or D₁≠D₂=D₃). These differing gap distances for each junction forming the asymmetric junction 104 cause the junctions to have differing critical currents (e.g., with a wider gap distance corresponding to a lower critical current), thereby removing inversion symmetry from the superconducting diode 300a and causing the device to act as a superconducting diode during operation. Although not depicted in the example of FIG. 3A, it should be understood that the junctions 330-1 and 330-2 may be switched such that the narrower junction 330-1 is disposed closer to the transverse electrode 108a than the wider junction 330-2, as aspects of the technology described herein are not limited in this respect.

In some embodiments, alternatively or additionally to forming the junctions 330-1 and 330-2 with different gap distances, the junctions 330-1 and 330-2 may be formed of different materials, as using different junction materials can cause each junction 330-1 and 330-2 to have different critical currents. For example, the junctions 330-1 and 330-2 may be each formed of different metals (e.g., one junction may be formed of gold and the other junction may be formed of copper) and/or of different insulators. In such embodiments, the junctions 330-1 and 330-2 may have a same gap distance or a different gap distance as is suitable to tune the operational parameters of the superconducting diode 300a.

In some embodiments, and as illustrated in FIG. 3A, a first bias electrode 106a and a second bias electrode 106b, respectively coupled to the first superconducting portion 102a and the second superconducting portion 102b, are provided, though it should be appreciated that the first bias electrode 106a and the second bias electrode 106b are optional as described in connection with FIG. 1 herein. Further, in some embodiments, the superconducting diode 300a may also include a transverse electrode 108a coupled to the first superconducting portion 102a.

As illustrated in the example of FIG. 3A, the bias electrodes 106a, 106b—if present—and/or transverse electrode 108a may be formed monolithically with the first superconducting portion 102a and/or the second superconducting portion 102b. Alternatively or additionally, discrete bias electrodes 106a, 106b and/or a discrete transverse electrode 108a may be provided in some embodiments. While no supporting circuitry (e.g., controller 114 or the one or more current source(s) 116) are depicted in FIG. 3A, it should be understood that such components may be present in an implementation of superconducting diode 300a.

FIG. 3A also shows illustrative paths of flow of a bias current 310 and a transverse current 312 through the superconducting diode 300a. In some embodiments, and as illustrated in FIG. 3A, during operation of the superconducting diode 300a the bias current 310 may be configured to flow from the first superconducting portion 102a to the second superconducting portion 102b. Alternatively, in some embodiments, the bias current 310 may be configured to flow from the second superconducting portion 102b to the first superconducting portion 102a during operation of the superconducting diode 300a (e.g., by coupling the first bias electrode 106a to ground and coupling the second bias electrode 106b to a current source).

In some embodiments, the bias current 310 may be applied with a magnitude limited by the critical current density of the superconducting diode 300a. For example, the magnitude of the bias current 310 may be any magnitude at which the superconducting diode 300a remains superconducting, taking into consideration factors such as operating temperature, materials used to fabricate the superconducting diode 300a, and dimensions of the components of the superconducting diode 300a.

In some embodiments, the transverse current 312 may be configured to flow from or to a first transverse electrode 108a. Due to the asymmetry of the asymmetric junction 104, the transverse current 312 may flow along a direction substantially orthogonal to the direction of the bias current 310 and/or along a direction substantially parallel to interfaces between the first superconducting portion 102a and the junctions 330-1 and 330-2. The magnitude of transverse current may be used to tune an efficiency of the superconducting diode 300a, and the direction of transverse current 312 may be used to control a polarity of the superconducting diode 300a.

FIG. 3B is a schematic diagram of an illustrative superconducting diode 300b having a plurality of arms, each including an associated Josephson junction, and a second transverse electrode 308b, according to some embodiments. FIG. 3B differs from FIG. 3A in that superconducting diode 300b is provided with a second transverse electrode 308b. In some embodiments, the function of the second transverse electrode 308b is analogous to that of the second transverse electrode 108b described in conjunction with the example of FIG. 2B herein. It should be appreciated that in some embodiments the superconducting diode 300a or superconducting diode 300b may include only the transverse electrode 108b, as aspects of the technology described herein are not limited in this respect.

FIG. 3C is a schematic diagram of an illustrative superconducting diode 300c having multiple arms, each arm including an associated Dayem bridge, in accordance with some embodiments of the technology described herein. FIG. 3C differs from FIG. 3B in that the asymmetric junction 104 includes Dayem bridges 340-1 and 340-2 in place of Josephson junctions 330-1 and 330-2.

In some embodiments, the asymmetric junction 104 of superconducting diode 300c includes a first Dayem bridge 340-1 having a different geometry than the second Dayem bridge 340-2, thereby causing the Dayem bridges 340-1 and 340-2 to have different critical currents. As shown in the example of FIG. 3C, the Dayem bridges 340-1 and 340-2 are formed by a superconducting portion that has a first edge parallel to the corresponding edge of the first superconducting portion 102a and second superconducting portion 102b, and two inwardly sloping edges opposite the first edge and meeting at a vertex point (e.g., either a sharp vertex or a constriction having a length, as in a wire-like structure). In some embodiments, Dayem bridge 340-1 has a thickness D₁, and Dayem bridge 340-2 has a gap distance of D₂>D₁. However, it should be appreciated that the geometries of the Dayem bridges 340-1 and 340-2 may be asymmetric in alternative or additional ways (e.g., a steepness of the inward sloping may be different such that the length of the Dayem bridge constriction along the X-direction may be different between the Dayem bridges 340-1 and 340-2).

It should further be appreciated that in embodiments having three or more junctions that each of the three or more junctions should have differing thicknesses (e.g., D₁≠D₂≠D₃). These thicknesses for each Dayem bridge forming the asymmetric junction 104 cause the junctions to have differing critical currents, thereby removing inversion symmetry from the superconducting diode 300c and causing the device to act as a superconducting diode during operation. Although not depicted in the example of FIG. 3C, it should be understood that the Dayem bridges 340-1 and 340-2 may be switched such that the narrower Dayem bridge 340-1 is disposed closer to the transverse electrodes 108a and/or 108b than the wider Dayem bridge 340-2, as aspects of the technology described herein are not limited in this respect.

Alternatively or additionally, in some embodiments, the superconducting diodes 300a, 300b, and/or 300c may be constructed with an asymmetric junction 104 including both Josephson junctions and Dayem bridges.

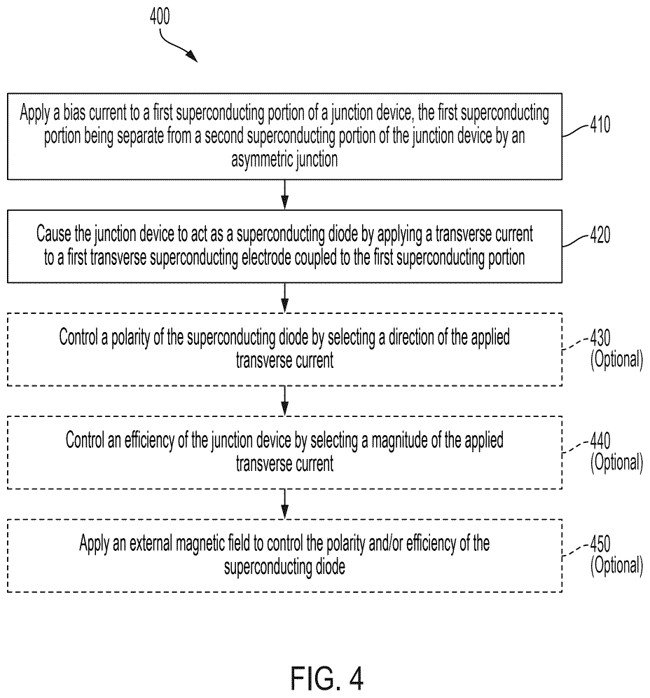

FIG. 4 is a flowchart illustrating a process 400 of operating a superconducting diode, in accordance with some embodiments of the technology described herein. During operation of the superconducting diode, the superconducting diode may be cooled to an operational temperature below a critical temperature of the superconducting material(s) used to form the superconducting diode.

In some embodiments, process 400 begins at act 410, wherein a bias current may be applied to a first superconducting portion of a junction device wherein the first superconducting portion is separated from a second superconducting portion of the junction device by an asymmetric junction. The bias current may be applied by a controller via a current source and may have a magnitude up to a critical current of the junction device.

In some embodiments, after act 410, the process 400 may proceed to act 420 in which the junction device may be caused to act as a superconducting diode by the application of a transverse current to a first transverse superconducting electrode coupled to the first superconducting portion. The transverse current may be applied by a controller via a current source. In some embodiments, during or after act 420, a second transverse current may optionally be applied to a second transverse superconducting electrode coupled to the junction device.

In some embodiments, during or after act 420, the process may optionally proceed to act 430 in which a polarity of the superconducting diode may be controlled by selecting a direction of the applied transverse current and/or the second transverse current, if present. The direction of the applied transverse current may be adjusted dynamically as desired for the operation of the superconducting diode.

In some embodiments, during or after act 430, the process may optionally proceed to act 440 in which an efficiency of the superconducting diode may be controlled by selecting a magnitude of the applied transverse current and/or the second transverse current, if present. The magnitude of the applied transverse current may be adjusted dynamically as desired for the operation of the superconducting diode, although for many applications a higher efficiency may be superior in all contemplated circumstances.

In some embodiments, during or after act 440, the process 400 may optionally proceed to at 450 in which an external magnetic field is applied to further control the polarity and efficiency of the superconducting diode. While, as described previously, the techniques disclosed herein are advantageous in that they do not require the application of an external magnetic field to achieve superconducting diode functionality, they are not incompatible with the application of external magnetic fields. Thus, if desired for greater control of efficiency or as dictated by other operational requirements of an apparatus in which a superconducting diode may be integrated, an external magnetic field may be applied.

An illustrative implementation of a computer system 500 that may be used in connection with any of the embodiments of the technology described herein (e.g., such as the method of process 400) is shown in FIG. 4. The computer system 500 includes one or more processors 510 and one or more articles of manufacture that include non-transitory computer-readable storage media (e.g., memory 520 and one or more non-volatile storage media X530). The processor 510 may control writing data to and reading data from the memory 520 and the non-volatile storage device 530 in any suitable manner, as the aspects of the technology described herein are not limited to any particular techniques for writing or reading data. To perform any of the functionality described herein, the processor 510 may execute one or more processor-executable instructions stored in one or more non-transitory computer-readable storage media (e.g., the memory 520), which may serve as non-transitory computer-readable storage media storing processor-executable instructions for execution by the processor 510.

Computing system 500 may also include a network input/output (I/O) interface 540 via which the computing device may communicate with other computing devices (e.g., over a network), and may also include one or more user I/O interfaces 550, via which the computing device may provide output to and receive input from a user. The user I/O interfaces may include devices such as a keyboard, a mouse, a microphone, a display device (e.g., a monitor or touch screen), speakers, a camera, and/or various other types of I/O devices.

The above-described embodiments can be implemented in any of numerous ways. For example, the embodiments may be implemented using hardware, software, or a combination thereof. When implemented in software, the software code can be executed on any suitable processor (e.g., a microprocessor) or collection of processors, whether provided in a single computing device or distributed among multiple computing devices. It should be appreciated that any component or collection of components that perform the functions described above can be generically considered as one or more controllers that control the above-discussed functions. The one or more controllers can be implemented in numerous ways, such as with dedicated hardware, or with general purpose hardware (e.g., one or more processors) that is programmed using microcode or software to perform the functions recited above.

In this respect, it should be appreciated that one implementation of the embodiments described herein includes at least one computer-readable storage medium (e.g., RAM, ROM, EEPROM, flash memory or other memory technology, CD-ROM, digital versatile disks (DVD) or other optical disk storage, magnetic cassettes, magnetic tape, magnetic disk storage or other magnetic storage devices, or other tangible, non-transitory computer-readable storage medium) encoded with a computer program (i.e., a plurality of executable instructions) that, when executed on one or more processors, performs the above-discussed functions of one or more embodiments. The computer-readable medium may be transportable such that the program stored thereon can be loaded onto any computing device to implement aspects of the techniques discussed herein. In addition, it should be appreciated that the reference to a computer program which, when executed, performs any of the above-discussed functions, is not limited to an application program running on a host computer. Rather, the terms computer program and software are used herein in a generic sense to reference any type of computer code (e.g., application software, firmware, microcode, or any other form of computer instruction) that can be employed to program one or more processors to implement aspects of the techniques discussed herein.

The foregoing description of implementations provides illustration and description but is not intended to be exhaustive or to limit the implementations to the precise form disclosed. Modifications and variations are possible in light of the above teachings or may be acquired from practice of the implementations. In other implementations the methods depicted in these figures may include fewer operations, different operations, differently ordered operations, and/or additional operations. Further, non-dependent blocks may be performed in parallel.

It will be apparent that example aspects, as described above, may be implemented in many different forms of software, firmware, and hardware in the implementations illustrated in the figures. Further, certain portions of the implementations may be implemented as a “module” that performs one or more functions. This module may include hardware, such as a processor, an application-specific integrated circuit (ASIC), or a field-programmable gate array (FPGA), or a combination of hardware and software.

Having thus described several aspects and embodiments of the technology set forth in the disclosure, it is to be appreciated that various alterations, modifications, and improvements will readily occur to those skilled in the art. Such alterations, modifications, and improvements are intended to be within the spirit and scope of the technology described herein. For example, those of ordinary skill in the art will readily envision a variety of other means and/or structures for performing the function and/or obtaining the results and/or one or more of the advantages described herein, and each of such variations and/or modifications is deemed to be within the scope of the embodiments described herein. Those skilled in the art will recognize or be able to ascertain using no more than routine experimentation many equivalents to the specific embodiments described herein. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, kits, and/or methods described herein, if such features, systems, articles, materials, kits, and/or methods are not mutually inconsistent, is included within the scope of the present disclosure.

The above-described embodiments can be implemented in any of numerous ways. One or more aspects and embodiments of the present disclosure involving the performance of processes or methods may utilize program instructions executable by a device (e.g., a computer, a processor, or other device) to perform, or control performance of, the processes or methods. In this respect, various inventive concepts may be embodied as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other tangible computer storage medium) encoded with one or more programs that, when executed on one or more computers or other processors, perform methods that implement one or more of the various embodiments described above. The computer readable medium or media can be transportable, such that the program or programs stored thereon can be loaded onto one or more different computers or other processors to implement various ones of the aspects described above. In some embodiments, computer readable media may be non-transitory media.

The terms “program” or “software” are used herein in a generic sense to refer to any type of computer code or set of computer-executable instructions that can be employed to program a computer or other processor to implement various aspects as described above. Additionally, it should be appreciated that according to one aspect, one or more computer programs that when executed perform methods of the present disclosure need not reside on a single computer or processor but may be distributed in a modular fashion among a number of different computers or processors to implement various aspects of the present disclosure.

Computer-executable instructions may be in many forms, such as program modules, executed by one or more computers or other devices. Generally, program modules include routines, programs, objects, components, data structures, etc. that perform particular tasks or implement particular abstract data types. Typically, the functionality of the program modules may be combined or distributed as desired in various embodiments.

When implemented in software, the software code can be executed on any suitable processor or collection of processors, whether provided in a single computer or distributed among multiple computers.

Further, it should be appreciated that a computer may be embodied in any of a number of forms, such as a rack-mounted computer, a desktop computer, a laptop computer, or a tablet computer, as non-limiting examples. Additionally, a computer may be embedded in a device not generally regarded as a computer but with suitable processing capabilities, including a Personal Digital Assistant (PDA), a smartphone, a tablet, or any other suitable portable or fixed electronic device.

Also, a computer may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible formats.

Such computers may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

### EXAMPLE

Characterization and control over the super current flow is useful for the application of Josephson junctions (JJs), which have become a building block in quantum and classical technology while remained a rich area of exploration into fundamental particles and unconventional superconductivity. Compared to spectroscopic probes that measures the amplitude of the superconducting (SC) wave function, the supercurrent flow encodes the SC phase. Mapping the spatial distribution of supercurrent has revealed the pairing symmetry of unconventional superconductors, and recently identified screening current as the source of SC diode effect in SC/ferromagnet structures. In addition, the local super current flow affects device parameters such as the impedance of SC circuits and anharmonicity of SC qubits due to the change in kinetic inductance. Despite the scientific and technological relevance, direct visualization of the Josephson current flow and its response to external tuning knobs such as bias current and magnetic field remains experimentally beyond reach. This is mostly due to the sensitive nature of the JJ, which responds to small perturbations and the nanoscale spatial resolution needed to resolve the evolution of the super current flow. To date, JJ characterization has primarily relied on indirect measurements such as the critical current that separates the dissipation-less (zero electrical resistance) and resistive states. However, this only provides insight into the resistive state while the ground state below the critical current stays hidden.

Here the current flow in a JJ device was quantitatively visualized with nanoscale resolution. The spatial distribution of Josephson current flow can be modulated by varying the SC phase difference between two sides of the junction. In any JJ, the SC phase difference is governed by three factors: (i) external magnetic field; (ii) external bias current; (iii) self-field or SC phase gradient induced by the finite Josephson current density. These measurements reveal the evolution of Josephson current flow with all three factors, including features associated with the change of the number of current loops at the junction known as the Josephson vortex (JV). In particular, factors (i) and (ii) can affect (iii), altering the super current flow even without detectable transport features. Two previously unidentified effects of the Josephson current-induced phase from factor (iii) were found. First, hidden ground states with different numbers of JVs are found within the zero-resistance state, which can be electrically switched below the critical current. Second, a new mechanism for the Josephson diode effect is established based on the second harmonic phase terms induced by the Josephson current when time-reversal and inversion symmetry are broken.

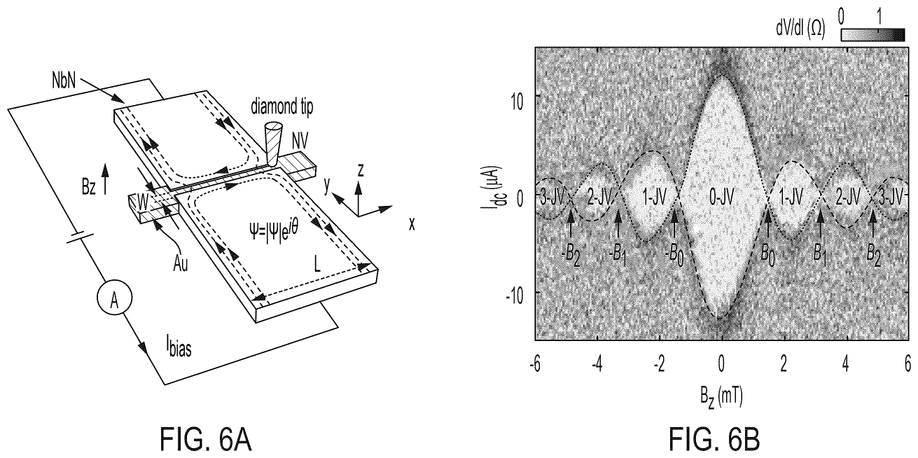

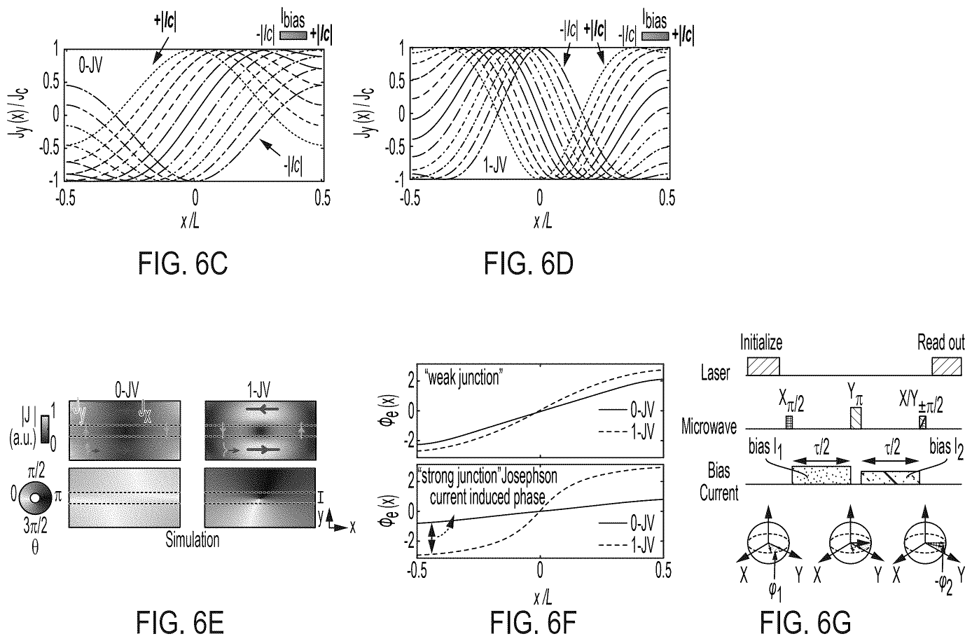

The measurement setup is shown in FIG. 6A. A diamond tip containing a single nitrogen vacancy (NV) center was employed to map the local magnetic field generated by the current flow. The results are obtained from two devices with junction width W=0.15 and 0.2 μm, length L=1.5 μm and thickness t=35 nm. The SC electrodes are measured to be in the thin-film limit L<<λₚ, where λₚ is the Pearl length. This suggests the factor (iii) contribution in the device comes from the Josephson current-induced phase associated with the kinetic inductance of the SC film, instead of the self-field effect. The junctions are diffusive (electron mean free path l_{mfp}<W) and over-damped (no hysteresis during bias current sweeps). In this example, the transverse (longitudinal) direction is referred to as x(y), and the direction perpendicular to the plane is referred to as z. The origin x=y=0 is set to the center of JJ.

### Results

### Current-Induced Phase

The Josephson current density can be modeled by the sinusoidal current-phase relation

$${J}_{y} ( x ) = {J}_{c} sin [ ϕ ( x ) ] , \qquad ( 1 )$$

where J_{c} is the Josephson critical current density (assumed constant for now), and φ(x) is the phase difference across the JJ at position x. φ(x)=φₑ(x)+φ_{bias}, where φₑ(x) arises from the external magnetic field B_{z} (factor i), and φ_{bias} is the additional phase difference due to the injected bias current (factor ii). The strength of Josephson current induced phase (factor iii) is regulated by J_{c}. For small J_{c}, the Josephson penetration length

$${λ}_{j} \approx \sqrt{{Φ}_{0} Lt / 4 {πμ}_{0} {J}_{c} {λ}_{L}^{2}} >> L ,$$

the Josephson current-induced phase can be neglected (“weak junction” limit). Φ₀ is the flux quantum, and λ_{L} is the London penetration length.

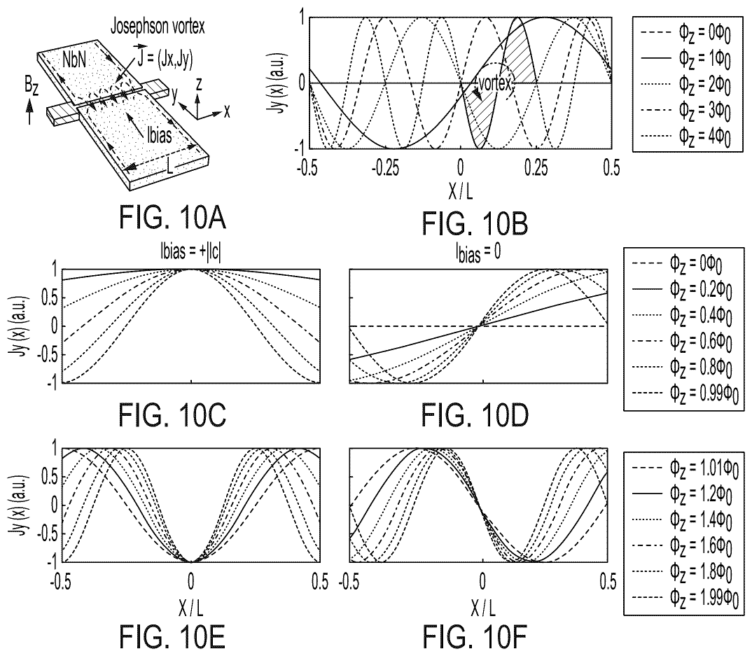

In the weak-junction limit, the external B_{z} controls the number of JVs. The transport critical current I_{c} oscillates and reaches zero at nodes Bz=±Bₙ (where n is an integer). It is known as the “Fraunhofer map.” In each lobe where Bₙ₋₁<|B_{z}|<Bₙ, there are nJVs at the junction; in the central lobe there is 0 JV (FIG. 6B); the only way to change the number of JVs is by sweeping B_{z} through the nodes Bₙ (FIGS. 10A-10F). In weak junctions the first term φₑ(x) is induced by the screening current Jₓ in the SC electrodes, and scaled by φₑ₀=θₑ|_{x=L/2}≈1.7B_{z}L²/φ₀³¹ (Equation 12). The second term φ_{bias} changes from −π2+nπ to π/2+nπ when I_{bias} sweeps from −|I_{c}| to +|I_{c}| (FIGS. 6C-6D), which can be viewed as moving the JV along the xx direction.

In “strong junctions” (λⱼ<<L), φ(x) is altered by the Josephson current-induced phase and lacks analytical solutions. Qualitatively, the screening current Jₓ deviates from the weak-junction limit by an amount proportional to the Josephson current J_{y} (FIG. 6E), due to the continuity of current. This leads to additional phase gradient ∂θ/∂x∝ [symbol] Jₓ, which changes φₑ(x)=θ(x)|_{y=w/2}−θ(x)|_{y=-w/2}. Here [symbol] is the kinetic inductance, which is inversely proportional to the superfluid stiffness. θ is the SC phase. Specifically, the larger Jₓ in the 1-JV state leads to enhanced φₑ₀, compared to the 0-JV state at the same external magnetic field (FIG. 6F). I_{bias} can further change the Josephson current and its induced phase. Thus in strong junctions, the total φ(x) and current flow need to be solved self-consistently. It is found that the device is close to the weak-junction limit at T=7 K, but is in an intermediate range at T=4 K.

### Visualizing Josephson Current Flow

To optimize magnetic field sensitivity, the “AC magnetometry” protocol was utilized, synchronizing NV control pulses with the signal (FIG. 1G). In this protocol, different bias currents I₁ and I₂ is applied to the junction during two halves of each cycle. The magnetic field generated by Iₖ rotates the prepared NV spin superposition state along the equator of the Bloch sphere by an angle φₖ=2πγₑbₙᵥτ/2, where γₑ is the gyromagnetic ratio of electron spin, bₙᵥ is the magnetic field projected along the NV axis, and t is cycle duration. After the sequence, the accumulated angle is φ₁-φ₂ so each measurement records the difference between two selected scenarios. bₙᵥ is converted to vector components of the magnetic field b_{x,y,z} using a Fourier method (see Methods). The current vector (jₓ,j_{y}) is then reconstructed with the Fourier method using in-plane components of the magnetic field. Similar results were found with regularization and machine learning methods.

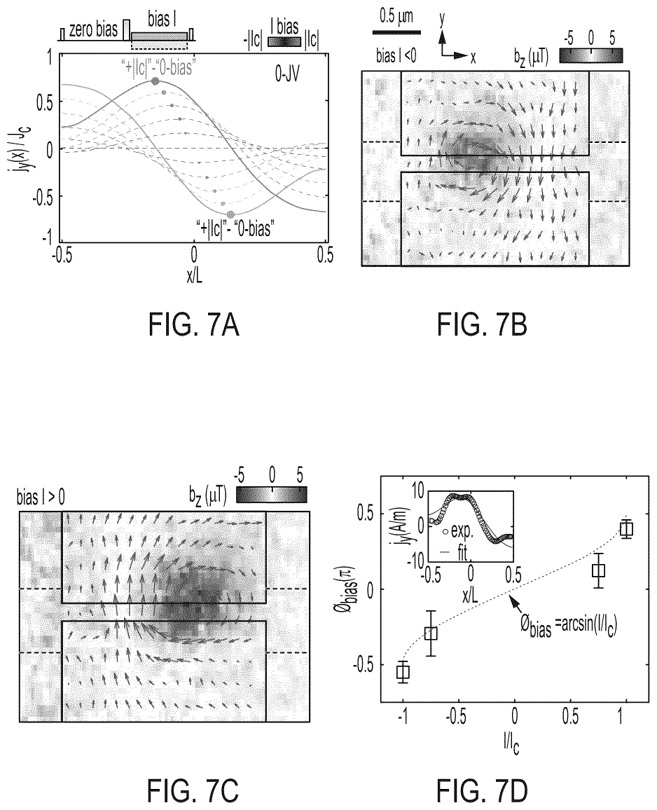

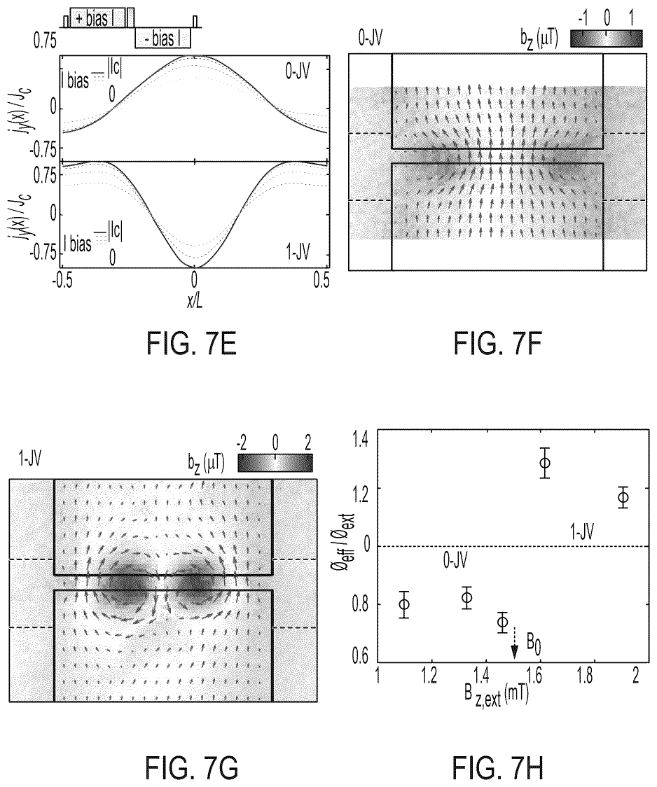

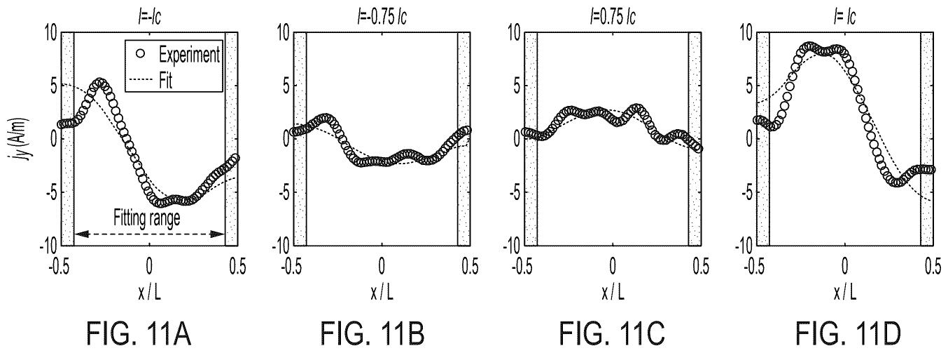

T=7 K was started with, where the transport result suggested a weak junction (FIG. 6B). To visualize the evolution of Josephson current, two types of sequences were used. In the first sequence, the effect of φ_{bias} was highlighted by taking the difference between finite and zero I_{bias} (schematics in FIG. 7A). The expected current profiles j_{y}(x) are shown in FIG. 7A, by subtracting the relevant lines in FIG. 6C. The sign of I_{bias} determines the direction of the profile shift and the amplitude determines the amount of the shift. FIGS. 7B-7C show measurements using I_{bias}≈±|I_{c}| in the sequence while no JV is in the junction. As expected, current features are seen at the opposite side of the junction for ±bias. j_{y}(x) at the junction also shows the lateral movement when sweeping I_{bias} (FIGS. 11A-11D). φ_{bias} can be acquired by fitting j_{y}(x) to the calculated profiles from FIG. 7A (Equation 13). The result agrees with the sinusoidal current-phase relation (FIG. 7D).

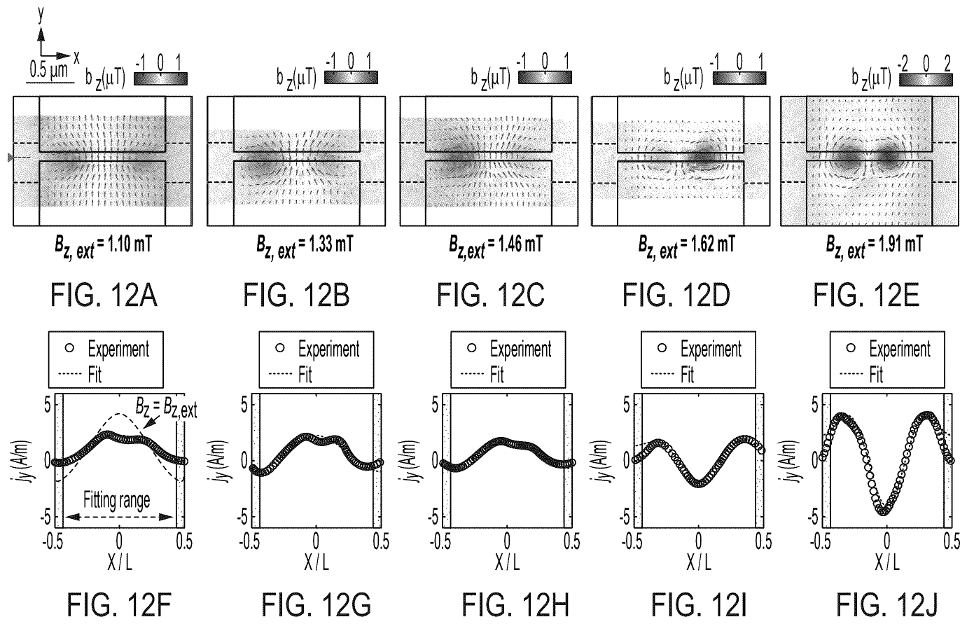

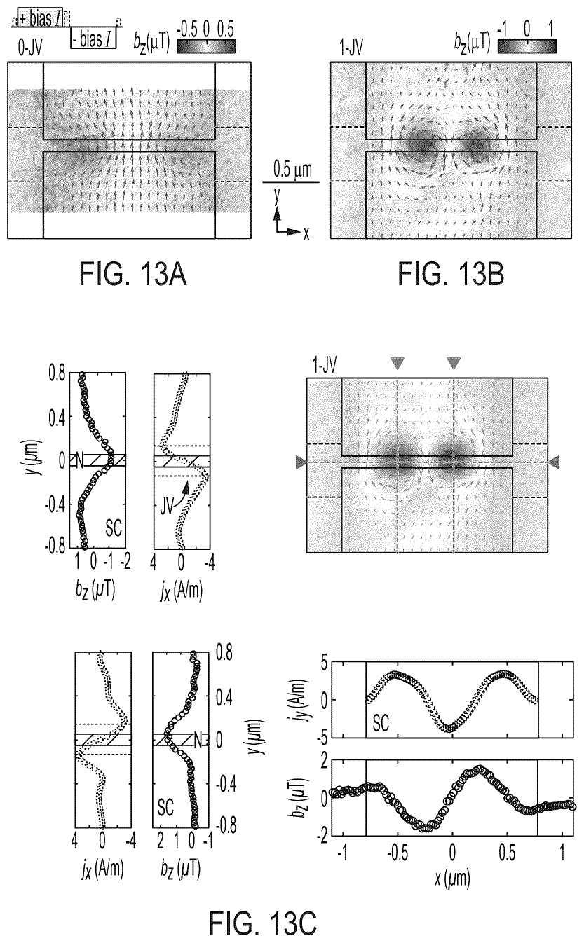

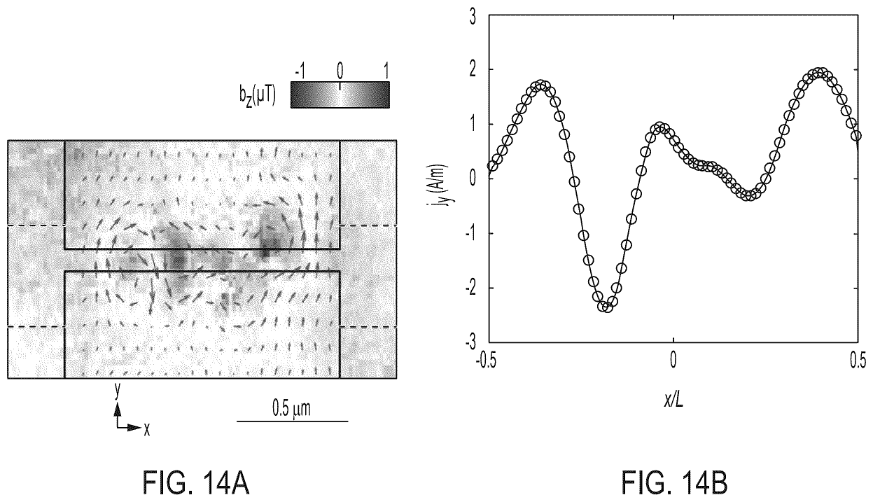

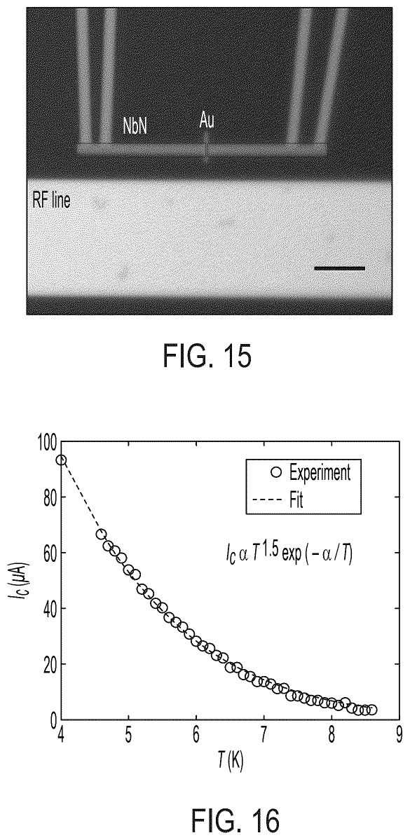

Next the effect of magnetic flux on the Josephson current was shown by taking the difference between ±I_{bias} (schematics in FIG. 7E). Here the expected signals are cosine-like and only grow in amplitude with I_{bias} (FIG. 7E). For the same I_{bias} direction, the signal flips sign for 0- and 1-JV states (switching from red to blue branch in FIG. 6B). Measurements using this sequence are shown in FIGS. 7F-7G, where I_{bias}≈|I_{c}| was used in both cases. Results measured at I_{bias}≈0.5|I_{c}| show the same shape with half the amplitude (FIGS. 13A-13B). The measurement was repeated at various magnetic fields, and the current profile reversal can be seen when external B_{z} crosses the node B₀≈1.5 mT, i.e., when JV number changes by 1 (FIGS. 12A-12J). Notably, the current flow at x=0 is parallel (anti-parallel) to I_{bias} when the junction contains even (odd) number of JVs. In the 2-JV state, the current flow at x=0 and bias current are both positive (FIGS. 14A-14B), like the 0-JV state (FIG. 7F).

These measurements provide quantitative details of the current flow compared to previous methods. First, the SC was confirmed to be in the thin-film limit (L<<λₚ). The absolute value of λₚ≈13 μm at T=7 K is directly measured from the stray field. In comparison, indirect measurements of λₚ range from 1 to 5 μm (see Methods), and thus are unable to determine whether the SC is in the thin-film regime. Second, the JV extends into the SC electrode on both sides by ˜350 nm (FIG. 13C), consistent with the effective area expected from the nodes Bₙ. However, the measured j_{y}(x) profile does not match the expectation under external B_{z}. For example, at B_{z}=1.1 mT the j_{y}(x) in FIG. 7F is expected to be negative at x=±L/2, but stays positive in the experiment, suggesting a smaller than expected deo (FIG. 12F).

An effective phase difference φ_{eff} was introduced as a fitting parameter for the measured j_{y}(x), replacing the theoretically predicted φₑ₀ (Equation 14). FIG. 7H shows φ_{eff} is lower (higher) than the phase induced by the external field φₑₓₜ when B_{z}<B₀ (B_{z}>B₀). The discrepancy is a direct consequence of the Josephson current-induced phase, as expected in strong junctions. While λⱼ is comparable to L when calculated using experimentally measured parameters, no strong junction feature is observed in the “Fraunhofer map” (FIG. 6B). The Josephson current-induced phase only causes small changes to I_{c}, and the effect cancels out when tracking I_{c} over large range of B_{z}. However, such an effect is still pertinent to designing SC devices such as JJ arrays because the inductance of each junction is affected by the supercurrent flow.

### Electrically Switching JV Below |I_{c}|

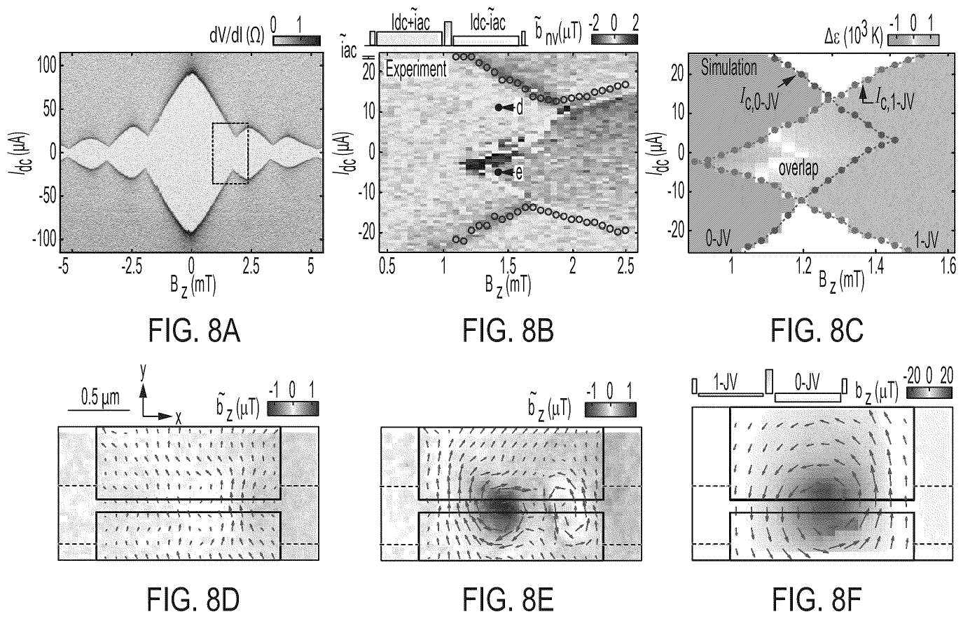

The “Fraunhofer map” changes when measured at T=4 K. The nodes of |I_{c}| at Bₙ are lifted although sharp kinks remain (FIG. 8A). This could be caused by a combination of reasons, including an asymmetric critical current density, J_{c}(x)≈J_{c}(−x) and the strong junction effect due to the increased |I_{c}|. However, the precise mechanism remains difficult to dissect owing to the zero-resistance below I_{c}. Here the origin of nonzero local minima of |I_{c}| is revealed by mapping the current flow. A differential magnetic field \tilde{b}ₙᵥ is measured using a sequence that senses the small ac bias (\tilde{t}_{ac}) response while fixing the DC bias (I_{dc}), shown by the schematic drawing above FIG. 8B. The \tilde{b}ₙᵥ is measured around the kinks of |I_{c}| while the NV is fixed over the center of the junction (FIG. 8B, main panel). Abrupt changes of \tilde{b}ₙᵥ at large |I_{dc}| match the transport I_{c} (circles in FIG. 8B). This suggests that the junction is minimally perturbed by the NV magnetometer.

An additional sharp boundary of \tilde{b}ₙᵥ below I_{c} separates the 0-JV and 1-JV states. This is confirmed by the spatial maps in FIGS. 8D-8E. In FIG. 8E (0-JV state), the current is almost uniform despite being measured at higher external B_{z} than FIG. 7F, suggesting φₑ₀ is strongly suppressed by the Josephson current-induced phase. Intriguingly, the 0-JV and 1-JV states can be reached at the same B_{z} but different I_{bias} (FIGS. 8D-8E). Measuring the difference between two such I_{bias}, the current profile that corresponds to the JV number changing by 1 is observed (FIG. 8F). This demonstrates precise JV number control using pure electric means while staying below I_{c}, which could be useful for low-dissipation memory and logic devices based on SC hybrid structures.

The phase boundary below I_{c} supports Josephson current-induced phase as the primary reason for the node-lifting in the device. The induced phase enables the co-stability of the 0-JV and 1-JV states originating from the existence of two local minima of the energy as a function of the order parameter Ψ(r) at the same external magnetic field, as shown by the time-dependent Ginzburg-Landau (TDGL) simulation (FIG. 8C). The overlapping states with different number of JVs were predicted to arise from the self-field effect previously. However, the self-field was not expected to be the main effect here. The measured self-field of the current is insignificant in the device (less than 5% of the external field), and the SC is still in the thin-film limit at T=4 K (L<<λₚ, see Methods). Furthermore, the boundary of the 0-JV and 1-JV phase diagram only extends from the 1-JV region (FIG. 8B) in the experiment. This is independent of sweeping directions of B_{z} or I_{dc}, and similar behavior is observed between the 1-JV and 2-JV states. The lack of hysteresis is quite unexpected. One possibility is that the JJ relaxes to the ground state with lower energy due to the elevated temperature and small perturbations of the measurement, although the detailed mechanism is an open question for future work. The simulated Gibbs free energy difference Δε=ε₀ₒᵥ−ε_{1|v} shows the 1-JV state has lower energy than the 0-JV state in most, but not all of the overlap region (FIG. 8C). In fact, including the self-field effect energetically favors the 0-JV over the 1-JV state, further deviating from the experimental results (FIGS. 20A-20F).

### Inversion Asymmetry and Josephson Diode Effect

The transport I_{c} is non-reciprocal when I_{bias} is applied in opposite directions at T=4 K, i.e.

$$\vert {I}_{c}^{+} \vert \neq \vert {I}_{c}^{-} \vert$$

(FIG. 9A). This is referred to as the “Josephson diode effect.” The asymmetry parameter,

$$η = \frac{\vert {I}_{c}^{+} \vert - \vert {I}_{c}^{-} \vert}{\vert {I}_{c}^{+} \vert + \vert {I}_{c}^{-} \vert} ,$$

exceeds 10% in the device. A new mechanism for the diode effect was identified comprising three ingredients, (i) time-reversal symmetry breaking (by B_{z}), (ii) inversion symmetry breaking, and (iii) Josephson currentinduced phase. The first two conditions are required by symmetry, while the third provides a mechanism whereby the Josephson current is not a simple sinusoidal function of φ_{bias}. As a result, the critical current density is reached on opposite sides of the junction at ±I_{bias}, which leads to asymmetric

$${I}_{c}^{\pm }$$

(FIG. 9B). Interestingly, it can be shown theoretically that first two ingredients alone are not sufficient to generate the diode effect; see Note 4, below. Combining the symmetry breaking with the Josephson current-induced phase introduces higher harmonic terms with a phase offset in the current-phase relation; see Note 4. These results confirm all three components are necessary. For example, the current profile measured at T=7 K is asymmetric, j_{y}(x)≠j_{y}(−x), suggesting broken inversion symmetry. However, the weaker current-induced phase due to smaller J_{c} is insufficient to generate a non-reciprocal global critical current response.

The current flow measurement directly reveals the broken inversion symmetry even when the global

$${I}_{c}^{\pm }$$

is almost symmetric. The \tilde{b}ₙᵥ map at ±_{bias} is measured at B_{z}=0.5 mT. Although η is only about 2%, the current flow pattern is clearly asymmetric for ±t_{bias}; a loop appears near the left edge for −I_{bias} (FIG. 9C) but not for +I_{bias} (FIG. 9D). The non-uniform J_{c}(x) was modeled with an uneven junction width W (W₁>W₂) in the TDGL simulation, confirming the role of broken inversion symmetry (FIGS. 9E-9F); if the junction is inversion symmetric, the ac current flow for ±g_{bias} should be mirrored along the x direction (FIGS. 21F-21H). In fact, the broken inversion symmetry is also responsible for the skewed phase boundary for +I_{bias} in FIGS. 8B-8C. In reality, the non-uniform J_{c}(x) could be due to variations in junction width, SC/normal barrier transparency, or normal metal resistivity.

### Discussion

The JV discussed herein should be distinguished from the Abrikosov vortex in type-II superconductors. While both move in the same direction with I_{bias} and exhibit normal cores, observed in spectroscopic studies, only the JV configuration can be controlled by a small change of I_{bias} below I_{c}. Even when the current-induced phase is weak, the JV can be precisely moved side-to-side by the small change of I_{bias} from −|I_{c}| to |I_{c}| at B_{z}=Bₙ±ε, (ε<<1). In particular, |I_{c}| should vanish at B_{z}=Bₙ, if the junction is symmetric about its midpoint. This control over the JV position enables for the observation of the large alternating magnetic field signal at the JJ with minimal changes in I_{bias} (FIG. 7G). Finally, the minimal energy cost associated with JV movement (I_{c}Δφ) as I_{c}→0 supports JV control as an energy-efficient way of communication between qubits.

The new mechanism of the Josephson diode effect offers a blueprint to realize a scalable SC rectifier with any thin-film SC. Conventional Josephson diodes that are driven by the self-field effect require a large operating current because the geometric inductance is usually small, especially at the nanoscale. However, the kinetic inductance can dominate in SC with small superfluid stiffness (e.g., low superfluid density), making it possible to reduce the device size. This also enables electric tuning of the Josephson diode by injecting a small current Jₓ to control the Josephson current-induced phase.

Finally, spatial mapping of the current flow J(x, y) presents an alternative observable to electrical transport in SC hybrid structures. By accurately measuring J (x, y) with high sensitivity and spatial resolution, the origin of the Josephson diode effect was pinpointed in the device, which was otherwise hidden. This approach opens up further avenues to unseal the mechanisms for the non-reciprocity in a broad range of SC systems, and symmetry breaking in gate-tunable superconductors based on van der Waals and moiré materials. The measured current flow could be directly compared with simulations based on TDGL or quantum transport to diagnose SC circuits, such as the local transparency of the JJ barrier.

### Methods

### Variable Temperature Scanning Setup

Measurements were performed in a home-built variable temperature system with optical access. There are multiple nano-pillars containing NV centers on each diamond probe, and a goniometer with both pitch and yawn control is used to set the stand-off distance between the NV and the sample, which ranges between 130 to 180 nm throughout the study. The NV center is excited with 532 nm green laser (Coherent Sapphire) and read out with standard optical detected magnetic resonance (ODMR) technique using a 600 nm long-pass optical filter. The time-averaged power of the green laser pulses is less than 50 μW. The microwave (MW) drive is provided via on-chip transmission line next to the sample. MW is sourced from SGS-100A (Rohde & Schwarz) and modulated with the built-in IQ mixer. MW pulses are then amplified by +40 dB using 30SIG6C (AR Inc) and routed through another switch (RF lambda) to reduce noise from the amplifier. MW and bias current control sequences are generated by arbitrary wave generator AWG5014C (Tektronic).

### Device Fabrication and Electrical Characterization

The SC and normal parts of the JJ are made of niobium nitride (NbN) and gold (Au) thin films, respectively. The JJs are fabricated on undoped Silicon substrate with 285 nm SiO 2 on top. Standard electron beam lithography method is used to define the device geometry using doublelayer e-beam resist. The normal part of the junction is first formed with thermal evaporation (2 nmTi/35 nmAu). A short Argon milling process is used right before sputtering SC electrodes (2 nmTi/6 nmNb/30 nm NbN). The MW strip line is formed with 2 nmTi/60 nm Au. Four terminal resistance result was first measured with de bias from Keithley 2400 and dc voltage with Keithley 2100, and then taken numerical derivative to acquire differential resistance shown above.

### Probe Fabrication and Typical Characteristics

The diamond fabrication process is known in the art. Specifically, ultra-pure diamond with natural 13C abundance and facet (electronic grade from Element Six) is diced into thin slabs ≈50 μm thick. One side of the slab is etched by Argon/Chloride plasma to relieve surface strain, then implanted with 15 N ions at a dose of 5×10¹⁰/cm² and acceleration energy of 6 keV (Innovion). Then the diamond is annealed in ultrahigh vacuum (<3×10⁻⁸ Torr) at 800° C. for 24 hours to form NV centers. The diamond nano-pillars are defined with standard e-beam lithography and etched with O₂ plasma. On average 1 NV center per diamond pillar was obtained with this process. The NV depth from the surface is about 15-20 nm. Typical ODMR red photon count is 100 k/s, contrast in pulsed measurement is 20 to 30%, and the coherence time is

$${T}_{2}^{*} \approx 1 μ s$$

and T₂≈30 μs at 4 K and the small magnetic field used herein.
Detail about NV Magnetometry

NV is a spin-1 system with low energy states s=|0 [symbol] , |+1 [symbol] . The |0 [symbol] is split in energy from |±1 [symbol] by the zero field splitting (2.87 GHz) and |±1 [symbol] are further split by the Zeeman energy E_{Z}=gμ_{B}Bₙᵥ, here g=2 is the Lande g-factor for electron, μ_{B} is the Bohr magneton, and Bₙᵥ is the magnetic field along NV axis. In practice, an external field of less than 50 G was applied along the NV axis, and the |0 [symbol] and |−1 [symbol] states were driven as a qubit using microwaves (MW). As described above, “AC” magnetometry is used to filter out low frequency noise and maximize sensitivity by utilizing the longer T₂ coherence time. Specifically, the NV qubit is first prepared in the |0 [symbol] state using a green laser pulse, and then driven into the superposition state

$$\frac{1}{\sqrt{2}} ( \vert 0 〉 + i \vert - 1 〉 ) by a {X}_{\frac{π}{2}} M W pulse .$$

Two types of dynamic decoupling sequences were used, the spin echo (Hahn echo) with one π-pulse, and the Carr-Purcell-Meiboom-Gill (CPMG) with n-Y_{π} pulses in the experiment. Between neighboring π-pulses, the qubit rotates by an angle φ=2πγₑbₙᵥτₙ, where γₑ=28 GHz/T is the gyromagnetic ratio of the electron spin, bₙᵥ is the magnetic field generated by the current projected along NV axis, and τₙ is the evolution time between neighboring MW pulses. The π-pulses reverse the qubit rotation direction, and the total angle is the difference of the accumulation in each half of the sequence. The frequency of NV control sequence and bias current modulation is f=100 to 500 kHz, corresponding to <1 nA bias current due to the AC Josephson effect I=hf/2eR_{N} (h is Planck's constant, e is electron charge, R_{N}˜1Ω is the normal state resistance of the JJ). This is 3 to 4 orders of magnitude smaller than the bias current applied to the JJ.

To extract the phase accumulation angle, the NV spin is projected to the |0) and |−1 [symbol] states using four

$$\frac{π}{2} - pulses {\frac{π}{2}}_{\pm X / Y}$$

and the ODMR signal is recorded. The angle is then calculated from

$$φ = arctan \frac{{C}_{\frac{π}{2} X} - {C}_{\frac{π}{2} - X}}{{C}_{\frac{π}{2} Y} - {C}_{\frac{π}{2} - Y}} \qquad ( 2 )$$

$$where {C}_{\frac{π}{2} \pm X / Y}$$

are the photon counts from

$${\frac{π}{2}}_{\pm X / Y}$$

projections. Ine measurement sequences are averaged up to 100 k times (about 10 seconds) at each point to extract the Bₙᵥ.
Reconstructing Current Flow from Magnetic Field

Discussed herein are the three methods used to reconstruct current flow j_{x,y} from bₙᵥ. For all methods, the magnetic field projected along NV axis bₙᵥ, was first converted to Cartesian vector magnetic field b_{x,y,z} using the source-free constraint for the stray field,

$$∇ \times b = 0 \qquad ( 3 )$$

Thus in the Fourier space the vector components are,

$${b}_{z} ( k ) = \frac{{b}_{nv} ( k )}{{u}_{nv} \cdot u} \qquad ( 4 )$$

$${b}_{x} ( k ) = - i \frac{{k}_{x}}{k} {b}_{z} ( k )$$

$${b}_{y} ( k ) = - i \frac{{k}_{y}}{k} {b}_{z} ( k )$$

here k=(kₓ,k_{y}) is the 2D wave vector,

$$k = \sqrt{{k}_{x}^{2} + {k}_{y}^{2}} ,$$

uₙᵥ is the unit vector of the NV axis
u=(−ikₓ/k,−ik_{y}/k,1). The singularity point at k=0 is discarded during the reconstruction. Because the SC electrode is much longer than the measurement window in the y direction, the j_{y} outside the window on the top and bottom sides also contribute to the measured bₙᵥ. In practice, the measured bₙᵥ was extended with the top and bottom lines in the y direction, and bₙᵥ was linearly extrapolated to zero in the x direction. The padding size in each direction is 10 times of the measurement window, at which point increasing the size does not change the reconstruction result.
Note 1. Evolution of Josephson Current Flow with External Magnetic Field in Weak Junctions

In this section, how external magnetic field B_{z} contributes to the evolution of Josephson current flow and JVs is evaluated. As discussed above, B_{z} affects φₑ(x), the profile of the super current, and modify the number of vortices trapped inside the junction. In the thin film, 1-D line junction (W<<L), and weak junction limit, φₑ(x)∝B_{z}·σ(x), where σ(x) is a non-linear function shown in Equation 12.

Here, σ(x) was simplified to a linear function to more intuitively show the magnetic field effect,

$${ϕ}_{e} ( x ) = 2 π \frac{{Φ}_{z}}{{Φ}_{0}} \frac{x}{L} .$$

Φ_{z}=B_{z}. A is the magnetic flux through the junction, A is the junction area. This applies to JJs made with bulk superconductors. Nevertheless it still captures the changes of the Josephson current flow with B_{z}. In this model, when B_{z} reaches the critical current nodes Φ_{z}=nΦ₀, the n-th JV enters the JJ (FIG. 10B).

Consider the Gibbs free energy of the junction without external bias current,

$$G ( {ϕ}_{bias} ) = \frac{{Φ}_{0}}{2 π} \cdot [ {I}_{c} ( {Φ}_{z} ) ( 1 - cos {ϕ}_{bias} ) ] \qquad ( 5 )$$

I_{c}(Φ_{z}) is the critical current when the external magnetic flux is 2, which changes sign at Φ_{z}=nΦ₀ (see Equation 6 and Note 1, below). As a result, the φ_{bias} which corresponds to the free energy minimum shifts by πt, and the local current density, ∝ sin [φₑ(x)+φ_{bias}] changes sign when a Josephson vortex enters/exits the junction.

The periodicity of the oscillating Josephson current J_{y}(x) shrinks with increasing Φ_{z}, as seen by the current profile at the critical current (FIGS. 10C, 10E), and at zero bias current (FIGS. 10D, 10F). The J_{y}(x) profile changes sign as Φ_{z} crosses the node from 0.99Φ₀ to 1.01 Φ₀, and around every nΦ₀ thereafter (FIGS. 10D, 10F).

It is noted that in the thin film limit and weak junctions, the JVs enter the junction at critical current nodes Bₙ as mentioned above. But at the nodes, the magnetic flux through the effective area A_{eff}=L²/1.842, Bₙ·A_{eff} is not exactly nΦ₀[6]. For example, at B₀ the magnetic flux through the effective area is 0.817300, as shown in Table 1. Nevertheless, the J_{y}(x) periodicity and sign changes with B_{z} still apply.

In summary, external magnetic flux manipulates Josephson current flow by changing the current profile and the number of JV, making it an important control knob in engineering SC devices.

Note 2. Josephson Current Flow And Sc Phase Difference Φ_{bias} At Finite Magnetic Flux

In this section, how the bias current I_{bias} controls the phase difference between SC electrodes φ_{bias}, at a finite external magnetic field B_{z}, is derived. Both (i) the bias current −φ_{bias} relation at finite B_{z} and (ii) the It phase shift associated with each JV in the junction are shown.

The junction spans between

$$x ∈ [ - \frac{L}{2} , \frac{L}{2} ]$$

are considered, so φ_{bias} is the phase difference between SC electrodes at x=0. The critical current density is assumed as constant J_{c}, and the simplified case,

$${ϕ}_{e} ( x ) = 2 π \frac{{Φ}_{z}}{{Φ}_{0}} \frac{x}{L} ,$$

is started with. Φ_{z}=B_{z}·A is the magnetic flux through the junction, A is the junction area. This applies to JJs made with bulk superconductors. The external bias current is

$${I}_{bias} = {\int }_{- L / 2}^{L / 2} J ( x ) dx = {\int }_{- L / 2}^{L / 2} {J}_{c} sin ( 2 π \frac{{Φ}_{z}}{{Φ}_{0}} \frac{x}{L} + {ϕ}_{bias} ) dx = {J}_{c} L sin c ( π \frac{{Φ}_{z}}{{Φ}_{0}} ) \cdot sin {ϕ}_{bias} \qquad ( 6 )$$

This shows the sinusoidal current-phase relation still applies at finite field. Here

$${I}_{c} ( {Φ}_{z} ) = {J}_{c} L \cdot sin c ( π \frac{{Φ}_{z}}{{Φ}_{0}} )$$

is the critical current at finite flux Φ_{z}. As a result, φ_{bias} can be controlled by I_{bias} via

$${ϕ}_{bias} = arcsin ( \frac{{I}_{bias}}{{I}_{c} ( {Φ}_{z} )} ) + n π \qquad ( 7 )$$

where n is the number of JV, which shifts the phase difference by nit. Intuitively, each JV has 2π phase winding around itself and this leads to n phase difference at the center of the junction x=0.

The phase shift due to JV can also be understood from an effective Gibbs free energy of the junction. The bias current adds a term to Eq. (2), giving

$$G = \frac{{Φ}_{z}}{2 π} \cdot [ {I}_{c} ( {Φ}_{z} ) ( 1 - cos {ϕ}_{bias} ) - {I}_{bias} {ϕ}_{bias} ] \qquad ( 8 )$$

This is the “washboard” potential for biased JJ, and for the over-damped junction, the equilibrium φ_{bias} occurs at the local minima of the free energy

$$( \frac{\partial G}{\partial {ϕ}_{b i a s}} = 0 and \frac{{\partial }^{2} G}{\partial {ϕ}_{b i a s}^{2}} > 0 ) .$$

For odd number of JV at the junction, I_{c}(Φ_{z})<0, which leads to the π phase shift when JV enters or exits the junction.

In the thin film weak-junction limit, φₑ(x) is given by Equation 12. The total current is then given by

$${I}_{b i a s} = Im {\int }_{- L / 2}^{L / 2} {J}_{c} ( x ) {e}^{i [ {ϕ}_{e o} σ ( x ) + {ϕ}_{b i a s} ]} dx ≡ {I}_{c} ( {B}_{z} ) sin [ {ϕ}_{b i a s} + {ϕ}_{c} ] \qquad ( 9 )$$

$$where$$

$${I}_{c} ( {B}_{z} ) = \vert {\int }_{- L / 2}^{L / 2} {J}_{c} ( x ) {e}^{i {ϕ}_{e o} σ ( x )} dx \vert \qquad ( 10 )$$

$${ϕ}_{c} = arg ( {\int }_{- L / 2}^{L / 2} {J}_{c} ( x ) {e}^{i {ϕ}_{e o} σ ( x )} dx ) . \qquad ( 11 )$$

Equation 7 can still apply in the thin film limit. It is seen that in the weak-junction limit, the dependence of the current on phase remains sinusoidal even if J_{c} depends on x. In particular, when J_{c} is a constant, φ_{c}=0, and the current phase relation in Equation 7 can apply.

### Note 3 Thin Film Josephson Junction and Extracting Δφ, φ_{Eff}

Described herein is (i) transport evidence of the junction being in the thin film limit, and (ii) the fitting methods to extract Δφ and φ_{eff} shown in FIGS. 7D-7H.

i. Thin Film SC

In a junction with W<<L, φₑ(x) can be derived from the x-direction screening currents in the thin film SC leads, treated as semi-infinite strips with the boundary condition of zero Josephson current, J_{y}(x)=0 at y=0 (center of the junction). It is assumed the external contact electrodes are located at positions y=±H, with H>>L. To leading order all screening currents flow within the SC electrodes and hence the boundary condition. One then finds

$${ϕ}_{e} ( x , {B}_{z} ) = \frac{16 {B}_{z} {L}^{2}}{{π}^{2} {Φ}_{0}} \cdot σ ( πx / L ) ≡ {ϕ}_{e 0} \cdot σ ( πx / L ) \qquad ( 12 )$$

$$σ ( ζ ) = {{Σ}_{n = 0}^{n = ∞} ( - 1 )}^{n} \frac{sin ( 2 n + 1 ) ζ}{{( 2 n + 1 )}^{3}}$$

where Φ₀ is the flux quantum. σ(ζ) is an odd function of its argument and may be reasonably approximated by σ(ζ)≈sin ζ. The scale of φₑ is set by the quantity φₑ₀=φₑ|_{x=L/2}≈1.7B_{z}L²/Φ₀. In this model, the φₑ(x) is induced by the screening current in the SC electrodes. Its shape is determined by the σ(ζ) function and its amplitude φₑ₀, is proportional to the magnetic field B_{z}. As mentioned above, this model does not include the Josephson current induced phase in strong junctions.

The B_{z} periodicity for the critical current oscillation, in the limit of large magnetic field, is ΔB_{∞}=1.842φ₀/L². Refs. [6, 8] showed that in the thin film junction, the nodes Bₙ are not evenly spaced. In a device described herein, the lithographically defined dimension is L=1.5 μm, thus ΔB_{∞} should equal 1.88 mT. The ΔBₙ=Bₙ₊₁−Bₙ extracted from the measurement in FIG. 6B is given in Table 1.

TABLE 1
Spacing between the I_{c} nodes ΔBₙ = Bₙ₊₁ −
Bₙ. Upper table, first line is in units of mT, second line is normalized
by ΔB_{∞}. The lower row shows theoretical values from a previous study.

| units | ΔB₀ | ΔB₁ | ΔB₂ |
|---|---|---|---|
| mT | 1.48 | 1.76 | 1.78 |
| Normalized | 0.79 | 0.94 | 0.95 |
| Theory | 0.8173 | 0.9866 | 0.9946 |

It is noted that in most of the literature, a simplified model is used to estimate the periodicity of the Fraunhofer map. It assumes magnetic field penetration through an area A=LW′=L(W+2λ_{L}), where λ_{L} is the London penetration length. So the magnetic field periodicity is ΔBₛᵢₘA=Φ₀. This applies to JJs made with bulk superconductors (λ_{L}>>L). Translating this to the the thin film SC limit, an effective area λ_{eff}=L²/1.842, and

$${W}_{eff}^{′} = L / 1.842$$

are obtained. FIGS. 13A-13C show the size of the JV in the y-direction agrees with this

$${W}_{eff}^{′} .$$

ii. Extracting the φ_{bias} in FIG. 7D

In FIGS. 7B-7C, the measurement is taken by subtracting the I_{bias} case by the zero bias case. To extract the effective phase difference between SC electrodes φ_{bias}, the experimental results are fit to the following equation,

$${j}_{y} ( x ) = {J}_{c} \cdot [ sin ( {ϕ}_{e} ( x , {B}_{z} ) + {ϕ}_{b i a s} ) - sin ( {ϕ}_{e} ( x , {B}_{z} ) ) ] \qquad ( 13 )$$

Here J_{c} (critical current density) and φ_{bias} are the two fitting parameters, while L=1.5 μm, B_{z}=B_{z,ext}=0.95 mT are fixed parameters. The fitting results at each I_{bias} are shown in FIGS. 11A-11D.

iii. Extracting the Perf in FIG. 7H

In FIGS. 7F-7G, the measurement is taken by subtracting the I_{bias} case by the −I_{bias} case. The φ_{eff} shown in FIG. 7H is

$${ϕ}_{eff} = \frac{16 {B}_{eff} {L}^{2}}{{π}^{2} {Φ}_{0}} .$$

The external magnetic field induced phase is

$${ϕ}_{ext} = \frac{16 {B}_{z} {L}^{2}}{{π}^{2} {Φ}_{0}} .$$

The experimental results are fit to the following equation,

$$\begin{matrix}{j}_{y} ( x ) = {J}_{c} \cdot [ sin ( {ϕ}_{e} ( x , {B}_{z} ) + {ϕ}_{b i a s} ) - sin ( {ϕ}_{e} ( x , {B}_{z} ) - {ϕ}_{b i a s} ) ] \\ = 2 {J}_{c} sin {ϕ}_{b i a s} \cdot cos [ {ϕ}_{e} ( x , {B}_{eff} ) ] \\ ≡ {J}_{0} \cdot cos [ {ϕ}_{e} ( x , {B}_{eff} ) ]\end{matrix} \qquad ( 14 )$$

Here J₀ and B_{eff} are the fitting parameters, L=1.5 μm is fixed. The fitting results are shown in FIGS. 12F-12J.

In both cases of fitting φ_{bias} and φ_{eff}, the portions of the reconstructed j_{y}(x) with the distance to the edge of the SC smaller than the NV stand-off distance are excluded from the fitting process, to avoid the ringing and distortion effects of the reconstructed result near the edge.

Note 4. Josephson Diode Effect Arising from Symmetry Breaking and Josephson Current Induced Phase

Presented herein is an examination of the roles of time-reversal and inversion symmetry, and current flow induced phase in realizing the JDE as explained in FIGS. 9A-9F, using a model with two lumped JJs in parallel. From a phenomenological perspective, the minimum requirement for JDE is that the current phase relation contains more than just the first harmonic term, plus a phase offset, I(φ)=a₁ sin (φ)+a₂ sin (2φ+φ₀). The second harmonic term could be due to the ballistic transport in the JJ or high transparency of the SC/N interface, which are difficult to verify experimentally. Using a two-junction model, it is shown that broken time reversal and inversion symmetry, combined with the Josephson current induced phase can effectively cause such a second harmonic term in current phase relation, even when starting with only the first harmonic term for the diffusive and low-transparency JJ. Presented here is more analysis in the context of the Josephson diode effect.

FIG. 17A shows a schematic drawing of the two-junction model. The JJ studied herein could be regarded as a set of lumped JJs in parallel, so the simplest case of two lumped JJs with critical current J_{1,2} was considered. Inversion symmetry breaking is indicated by J₁≠J₂. The phase difference across the junction consists of the external magnetic field contribution fₑₓₜ, and the Josephson current induced phase f_{cip}. The total bias current across the junction is

$${I}_{b i a s} = {J}_{1} sin ( Δϕ - \frac{{f}_{e x t} + {f}_{c i p}}{2} ) + {J}_{2} sin ( Δ ϕ + \frac{{f}_{e x t} + {f}_{c i p}}{2} ) \qquad ( 15 )$$

where Δφϵ[−π,π] is the phase difference between the SC electrodes. The Josephson current induced phase of the left and right junctions is

$${f}_{cip} = {ℒ}_{k} [ {J}_{1} sin ( Δϕ - \frac{{f}_{e x t} + {f}_{c i p}}{2} ) - {J}_{2} sin ( Δ ϕ + \frac{{f}_{e x t} + {f}_{c i p}}{2} ) ] \qquad ( 16 )$$

where [symbol] is proportional to the kinetic inductance.

Three representative scenarios are discussed below.
1. Neglecting Josephson current induced phase. If f_{cip}=0 in Equation 15, the I_{bias} only contains the first harmonic term of Δφ with a phase offset, and JDE does not exist.
2. J₁=J₂. Equation 16 is reduced to f_{cip}=−2 [symbol] cos (Δφ) sin (fₑₓₜ+f_{cip}), which yields the same solutions of f_{cip} when Δφ↔−Δφ. This means I_{bias}(Δφ)=−I_{bias}(−Δφ), and JDE does not exist.
3. J₁≠J₂. In this case, f_{cip} needs to be solved numerically. Taking the limit of f_{cip}«fₑₓₜ, Δφ, i.e., [symbol] Jᵢ«1, terms in Equation 16 are expanded to first order of f_{cip}, and get:

$${f}_{c i p} ≃ {ℒ}_{k} [ {J}_{1} sin ( Δ ϕ - \frac{{f}_{e x t}}{2} ) - {J}_{2} sin ( Δ ϕ + \frac{{f}_{e x t}}{2} ) - \frac{{f}_{c i p}}{2} [ {J}_{1} cos ( Δ ϕ - \frac{{f}_{e x t}}{2} ) + {J}_{2} cos ( Δ ϕ + \frac{{f}_{e x t}}{2} ) ] ] . \qquad ( 17 )$$

Combining Equation 17 with Equation 15 yields:

$${I}_{b i a s} ≃ {J}_{1} sin ( Δ ϕ - \frac{{f}_{e x t}}{2} ) + {J}_{2} sin ( Δ ϕ + \frac{{f}_{e x t}}{2} ) ) - \frac{{f}_{c i p}}{2} [ {J}_{1} cos ( Δ ϕ - \frac{{f}_{e x t}}{2} ) - {J}_{2} cos ( Δ ϕ + \frac{{f}_{e x t}}{2} ) ] = {J}_{1} sin ( Δ ϕ - \frac{{f}_{e x t}}{2} ) + {J}_{2} sin ( Δ ϕ + \frac{{f}_{e x t}}{2} ) ) + \frac{{ℒ}_{k}}{2} \frac{{J}_{1}^{2} sin ( 2 Δ ϕ - {f}_{e x t} ) + {J}_{2}^{2} sin ( 2 Δ ϕ + {f}_{e x t} ) - 2 {J}_{1} {J}_{2} sin ( 2 Δ ϕ )}{2 + {ℒ}_{k} [ {J}_{1} cos ( Δ ϕ - \frac{{f}_{e x t}}{2} ) + {J}_{2} cos ( Δ ϕ + \frac{{f}_{e x t}}{2} ) ]} \qquad ( 18 )$$

Here the second harmonic term of Δφ with a phase shift is present, and JDE can be observed.

The critical current in the two-JJ model was also numerically solved for when the current flow induced phase was included. At each external magnetic flux fₑₓₜ, f_{cip} was first solved for at individual Δφϵ[−π,π] in Equation 16. The (f_{cip}, Δφ) is then plugged into Equation 15 to find the maximum (minimum) I_{bias} as

$${I}_{c}^{+} ( {I}_{c}^{-} ) .$$

Three cases of J₁₍₂₎ are considered. When the system is inversion symmetric, i.e., J₁=J₂, the current flow induced phase only lifts the node and does not manifest JDE (FIG. 17D) When J₁≠J₂>becomes

$${I}_{c}^{\pm }$$

becomes asymmetric when fₑₓₜ≠0. In particular, the JDE changes polarity when exchanging J₁ and J₂, or changing the sign of external field (FIGS. 17B-17C). The critical current nodes are near half-integer of Φ₀ because of the two lumped JJs in the model (effectively a SQUID), but it does not affect the interpretation.

It is noted that the above result also applies to the case with strong self-field effect, by replacing the kinetic inductance with the geometric inductance of the junction, and replacing the f_{cip} with the phase induced by the current-generated magnetic field.

The JDE has garnered much attention due to its application in low dissipation electronics, and some of the more recent interest has focused on the connection between JDE and finite momentum pairing of the Cooper pairs in the JJ. Herein, the origin of the observed JDE was pinpointed with a combination of measurements of electrical transport, and visualization of the current flow. The inversion symmetry breaking in the device likely arises from the non-uniform junction width or transparency ubiquitous in the nano-fabrication process. The Josephson current induced phase is revealed thanks to the local current flow mapping, because the JJ is not deep in the so-called “strong-junction” regime by the conventional metric. In the device L≈2λⱼ even at T=4 K, and the calculation of λⱼ depends on an estimate of λ_{L} which could vary from sample to sample. In this spirit, some additional ways to realize the JDE experimentally are summarized.
1. Trapped vortices in superconductors. The JDE requires breaking time reversal symmetry. This could come from the Abrikosov vortices (AV) trapped in thin film superconductors even after external magnetic field is retracted. When an AV is near the JJ, it causes a phase gradient along the transverse direction that mimics the effect of magnetic flux induced by external field. In the case of layered SC, JVs could be trapped between layers due to history of an in-plane magnetic field. Additionally, the trapped vortices could be caused by magnetic materials at the JJ or nearby.
2. Asymmetric injection of bias current. The inversion symmetry of the JJ could be broken by non-uniform critical current density. This could be due to local defects as mentioned above, or local temperature gradient. The effect could be further enhanced by engineering electrodes to intentionally inject the current asymmetrically to the JJ.
3. Multi-layer SC. When multiple kinds of SC with different critical current is used, or in the case of heterogeneous film quality along the normal direction, JDE could develop when an in-plane external field perpendicular to the junction is applied. The mechanism is similar to the one described above, for a JJ that exists in the yz plane and the external field is Bₓ.

### EQUIVALENTS

Having thus described several aspects and embodiments of the technology set forth in the disclosure, it is to be appreciated that various alterations, modifications, and improvements will readily occur to those skilled in the art. Such alterations, modifications, and improvements are intended to be within the spirit and scope of the technology described herein. For example, those of ordinary skill in the art will readily envision a variety of other means and/or structures for performing the function and/or obtaining the results and/or one or more of the advantages described herein, and each of such variations and/or modifications is deemed to be within the scope of the embodiments described herein. Those skilled in the art will recognize or be able to ascertain using no more than routine experimentation many equivalents to the specific embodiments described herein. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, kits, and/or methods described herein, if such features, systems, articles, materials, kits, and/or methods are not mutually inconsistent, is included within the scope of the present disclosure.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B,” when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

The use of “coupled” or “connected” is meant to refer to circuit elements, or signals, which are either directly linked to one another or through intermediate components. Elements that are not “coupled” or “connected” are “decoupled” or “disconnected.”

The terms “approximately,” “substantially,” and “about” may be used to mean within +20% of a target value in some embodiments, within +10% of a target value in some embodiments, within +5% of a target value in some embodiments, within +2% of a target value in some embodiments, and/or within +1% of a target value in some embodiments. The terms “approximately,” “substantially,” and “about” may include the target value.

What is claimed is:

1. A superconducting diode, comprising:
a junction device including a first superconducting portion and a second superconducting portion separated by an asymmetric junction; and
a transverse superconducting electrode coupled to the first superconducting portion.

2. The superconducting diode of claim 1, wherein:
the asymmetric junction comprises a material having a finite resistance at an operational temperature of the superconducting diode.

3. The superconducting diode of claim 2, wherein:
the material of the asymmetric junction comprises a geometric asymmetry.

4. The superconducting diode of claim 1, wherein:
the asymmetric junction comprises a Dayem bridge superconducting portion having a notch.

5. The superconducting diode of claim 1, further comprising:
a controller configured to, during operation of the superconducting diode:
cause application of a bias current to the first superconducting portion; and
cause application of a transverse current to the transverse superconducting electrode.

6. The superconducting diode of claim 1, wherein:
the first superconducting portion and the second superconducting portion each comprise a plurality of arms, and
the asymmetric junction comprises a plurality of junctions, each of the plurality of junctions connecting respective arms of the first superconducting portion and the second superconducting portion.

7. The superconducting diode of claim 6, wherein:
a first junction of the plurality of junctions is characterized by a critical current different than a critical current of a second junction of the plurality of junctions.

8. The superconducting diode of claim 7, wherein:
one or more junctions of the plurality of junctions comprise materials having a finite resistance at an operational temperature of the superconducting diode.

9. The superconducting diode of claim 8, wherein:
the one or more junctions comprise:
a first junction comprising a first material, and
a second junction comprising a second material, and
the first material and the second material are different.

10. The superconducting diode of claim 7, wherein:
the asymmetric junction comprises an asymmetry resulting from a geometry of one or more junctions of the plurality of junctions.

11. The superconducting diode of claim 10, wherein:
one or more junctions of the plurality of junctions comprise a Dayem bridge superconducting portion having a notch.

12. The superconducting diode of claim 1, wherein the transverse superconducting electrode is a first transverse superconducting electrode, and the superconducting diode further comprises:
a second transverse superconducting electrode coupled to the second superconducting portion.

13. The superconducting diode of claim 1, wherein:
the first superconducting portion and the second superconducting portion have a thickness of less than one hundred nanometers.

14. The superconducting diode of claim 1, wherein:
the first superconducting portion and the second superconducting portion are separated by a distance of less than one micrometer.

15. The superconducting diode of claim 1, wherein:
a distance from the asymmetric junction to the transverse superconducting electrode is less than one micrometer.

16. The superconducting diode of claim 1, wherein:
the first superconducting portion and the second superconducting portion comprise niobium nitride (NbN).

17. The superconducting diode of claim 1, wherein:
the first superconducting portion and the second superconducting portion comprise high temperature superconducting material.

18. A method of operating a superconducting diode, comprising:
applying a bias current to a first superconducting portion of a junction device, the first superconducting portion being separated from a second superconducting portion of the junction device by an asymmetric junction; and
causing the junction device to act as a superconducting diode by applying a transverse current to a first transverse superconducting electrode coupled to the first superconducting portion.

19. The method of claim 18, wherein applying the transverse current comprises:
controlling a polarity of the superconducting diode by selecting a direction of the applied transverse current.

20. The method of claim 18, wherein applying the transverse current comprises:
controlling an efficiency of the superconducting diode by selecting a magnitude of the applied transverse current.
